(19) United States
(12) Patent Application Publication
(10) Pub. No.: US 2024/0170411 A1
(43) Pub. Date: May 23, 2024

(54) SCRIBE LANE REINFORCEMENT

(71) Applicant: ADEIA SEMICONDUCTOR BONDING TECHNOLOGIES INC., San Jose, CA (US)

(72) Inventors: Xu CHANG, San Jose, CA (US); Rajesh KATKAR, Milpitas, CA (US)

(21) Appl. No.: 18/057,135

(22) Filed: Nov. 18, 2022

(51) Int. Cl. H01L 23/544; H01L 21/683; H01L 21/78; H01L 23/00

(52) U.S. Cl. CPC H01L 23/544; H01L 21/6835; H01L 21/78; H01L 24/08; H01L 24/80; H01L 2223/5446; H01L 2224/08145; H01L 2224/80895; H01L 2224/80896

(57) ABSTRACT

This disclosure relates to systems and methods for reinforced semiconductor structures. In some embodiments, an assembly can include a substrate having a top surface and a bottom surface and one or more layers formed on the top surface of the substrate. The one or more layers and the substrate can comprise a plurality of devices to be singulated into dies and a scribe region separating the devices, at least one layer of the one more layers comprising a first dielectric material. The one or more layers and substrate can also include a trench at least partially overlapping the scribe region and at least partially filled with a second dielectric material, wherein the second dielectric material has a higher dielectric constant than a dielectric constant of the first dielectric material, or otherwise more resistant to chipping or cracking than the first dielectric material.

### BACKGROUND

### Field

This disclosure relates to semiconductor device structures. Some embodiments relate to direct bonding.

### Description of Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

As features in semiconductor devices continue to shrink, low dielectric constant (low-k or low-K) and ultra-low-k dielectrics are increasingly important to provide electrical isolation between components within semiconductor devices. However, low-k and ultra-low-k dielectrics can be prone to cracking, delamination, and other issues, which can lead to device failure. In some cases, dicing through low-k and ultra-low-k dielectrics can produce particles that can make later processing steps, such as direct bonding, prone to defects.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A illustrates an example of a wafer comprising a plurality of dies.

FIG. 1B illustrates a side view of part of a wafer comprising a plurality of layers.

FIG. 2 illustrates an example dielectric fill and bonding process.

FIGS. 3A and 3B illustrate examples of filling a scribe lane with dielectric material.

FIG. 3C illustrates device dies after singulation having a direct bonding layer formed thereon.

FIGS. 4-9 illustrate various embodiments of semiconductor devices or wafers with backfilled oxides.

FIG. 10 illustrates an embodiment of a semiconductor device having arrestor regions disposed therein.

FIG. 11 illustrates and example embodiment of a semiconductor device that does not have a protective metal ring.

FIGS. 12-18 illustrate example processes for forming a relatively high-k dielectric material in a scribe region of a wafer comprising a plurality of devices.

FIGS. 19-22 illustrate example direct bonding processes.

FIGS. 23A-23B schematically illustrate a direct bonding process according to some embodiments.

### DETAILED DESCRIPTION

Although several embodiments, examples, and illustrations are disclosed below, it will be understood by those of ordinary skill in the art that the inventions described herein extend beyond the specifically disclosed embodiments, examples, and illustrations and includes other uses of the inventions and obvious modifications and equivalents thereof. Embodiments of the inventions are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the inventions. In addition, embodiments of the inventions can comprise several novel features and no single feature is solely responsible for its desirable attributes or is essential to practicing the inventions herein described.

As features in semiconductor devices become smaller and closer together, it is increasingly important to mitigate problems of charge buildup and crosstalk, which can adversely affect device performance. By replacing a conventional dielectric such as silicon dioxide, silicon nitride, etc. with a low-k or ultra-low-k dielectric, parasitic capacitance can be reduced, which can enable faster device performance, among other benefits. A low-k dielectric can have a dielectric constant that is less than the dielectric constant of silicon dioxide (e.g., less than about 3.9). For example, a low-k dielectric can have a dielectric constant of from about 2.7 to about 3.6, while an ultra-low-k material can have a dielectric constant below 2.7, for example of from about 1.8 to about 2.6.

Depending upon the application and manufacturing process, silicon dioxide or other relatively high-k dielectrics can be replaced with a variety of low-k or ultra-low-k dielectrics. For example, a low- or ultra-low-k material can be a silicon-containing compound such as fluorine-doped silicon dioxide, carbon-doped silicon oxide, organosilicate glass (e.g., SiCOH), porous silicon dioxide, porous organosilicate glass, porous carbon-doped silicon oxide, silsesquioxanes (e.g., hydrogen silsesquioxane, methyl silsesquioxane), and so forth. Low- or ultra-low-k materials can include non-Si-containing materials such as organic polymers (e.g., polyimide) or amorphous carbon. These are merely examples of potential materials and are not intended to be interpreted in a limiting manner. Other materials as described herein and/or as known to those of skill in the art may be used consistent with this disclosure.

One important way of manipulating the dielectric constant can be to control the porosity of the dielectric material. Porosity can be achieved due to self-organization of the material, with pore sizes typically less than about 2 nm and/or can be achieved via subtraction. For example, a different material or ingredient can be included during formation of the dielectric material and then later removed, for example by annealing, extreme ultraviolet (EUV) treatment, selective etching (e.g., using HF to remove Si—O from SiCOH), and so forth. Typically, porous materials prepared in such a manner can have pore sizes from about 2 nm to about 10 nm, or even more depending upon the specific process used to prepare the material. As just one example, SiCOH can have a dielectric constant of about 2.4, about 2.45, about 2.7, about 3.0, or number between any two of these numbers, or more or less, depending on the porosity of the material. In some cases, air gaps can be used as a dielectric material, although this can compromise the mechanical properties of the device or otherwise be impractical in some use cases. A dielectric material may be an organic material or an inorganic material. In some cases, a dielectric material can be formed by spinning, for example a silicon-based polymeric dielectric. In some cases, a dielectric material can be formed by chemical vapor deposition, physical vapor deposition, or other methods as known to those skilled in the art. In some cases, a layer may comprise a single dielectric material. In some embodiments, one or more layers can comprise a plurality of dielectric materials, and the plurality of dielectric materials can have an average dielectric constant. In some embodiments, different layers in a device can comprise different dielectric materials. For example, a first metallization layer can comprise a first dielectric material and a second metallization layer can comprise a second, different dielectric material, although in some embodiments, different layers may comprise the same dielectric material or materials.

A typical semiconductor device may comprise many layers over the bulk semiconductor material (e.g., about 2 layers to hundreds of layers, particularly for modern integrated circuits employing three-dimensionally stacked devices). The bottom layers in the semiconductor device can include electronic devices (e.g., switches such as transistors, capacitors, resistors, inductors, etc.). In some layers, local interconnects can be partially or fully surrounded by one or more low-k or ultra-low-k dielectric materials. In some embodiments, the interconnects can be spaced very close together. For example, local interconnects can have a pitch of from about 30 nm to about 80 nm, or more or less, depending upon the process node. Intermediate interconnects can typically have pitches that are from about two times to about two and a half times the pitch of the local interconnects. Global interconnects can typically have pitches that are from about three times to about four times the pitch of the local interconnects. In some embodiments, there can be very thick and/or wide metals that can be used in top-most levels of a device, where dimensions can be of lesser concern. In some embodiments, the dielectric material used in lower metallization levels, which can be considered intermediate interconnect levels between upper metallization levels and local interconnects, can have lower dielectric constants than the dielectric material or materials used in the upper metallization levels. Near the top surface, a semiconductor device can have from about 1 to about 10 global interconnect levels at upper metallization levels. The global interconnect levels may include one or more dielectric materials such as, for example, silicon oxide, fluorosilicate glass, and so forth that can have higher k-values than the intermediate interconnect levels. In some embodiments, a semiconductor device can have a direct bonding (e.g., DBI as described herein) layer disposed on top of a global interconnect layer. The skilled artisan will appreciate that the different types of interconnects at different levels can vary from device to device and from technology node to technology node.

While low-k dielectrics can offer significant advantages for advanced semiconductor devices, low-k/ultra-low-k materials can be fragile, and devices can be prone to breaking, cracking, delaminating, or other failures. For example, porous dielectrics and more exotic low-k materials can exhibit reduced stiffness and adhesion as compared with more conventional dielectrics such as silicon oxide, including TEOS. For example, devices may experience stress delamination and/or edge cracking resulting from singulation processes, thermo-mechanical stresses, etc.

Accordingly, it is desirable to develop systems and methods that can avoid or mitigate problems associated with low-k and ultra-low-k dielectrics. Mitigating such issues may improve device reliability, improve device performance, and/or increase yield. The fragility of ultra-low-k materials can be especially problematic in high-performance devices that use direct bonding where ultra-thin dies may be used and robust, reliable, and inexpensive singulation is important. The disclosures herein can provide alternative processes that can improve the yield of advanced node semiconductor device manufacturing processes. The systems and methods described herein, while advantageous in direct bonding (e.g., direct hybrid bonding) applications, are not limited to direct bonding applications. More information on direct bonding, including hybrid direct bonding, is provided below.

Low-k and ultra-low-k films are commonly used as insulators because of their ability to prevent crosstalk within a semiconductor device. The low dielectric constant can enable fast switching speeds and increased density of components within a single chip. However, these materials are typically fragile and prone to delamination and cracking, especially during singulation. Additionally, low-k dielectric layers can be a source of particles and other dicing debris that can interfere with direct bonding. Often oxide-based low-k materials can have relatively poor mechanical strength. In some embodiments, a polymer dielectric material can be more resistant to fracturing than an oxide-based low-k dielectric, but may also introduce difficult-to-remove particle contamination during singulation process.

Low-k and ultra low-k materials can often be characterized as having relatively small Young's moduli. For example, a thermally grown thin oxide film on a 111 silicon wafer can have a Young's modulus of from about 70 to about 76 GPa. It is believed that the Young's modulus of bulk silicon dioxide decreases from about 70-76 GPa to less than about 15 GPa (e.g., about 5 GPa to 15 GPa) as the porosity increases to about 50%. As another example, SiCOH with a dielectric constant of from about 2.4 to about 2.45 is generally considered as having Young's moduli of from about 5 GPa to about 10 GPa with a porosity of less than about 50%. It will be appreciated that variations in process, substrate material, measurement technique, and so forth can affect the Young's modulus.

In a conventional die-to-wafer (D2W) bonding process, known good dies (KGD) can be directly bonded to a carrier wafer and gaps between dies filled to form a reconstituted wafer. The KGDs can be thinned and through-silicon vias (TSVs) can be exposed and a direct bonding layer, which may include redistribution layer(s) (RDLs) prepared over the dies. Semiconductor dies, spacer or dummy dies, and so forth can then be direct hybrid bonded to the KGDs of the reconstituted wafer.

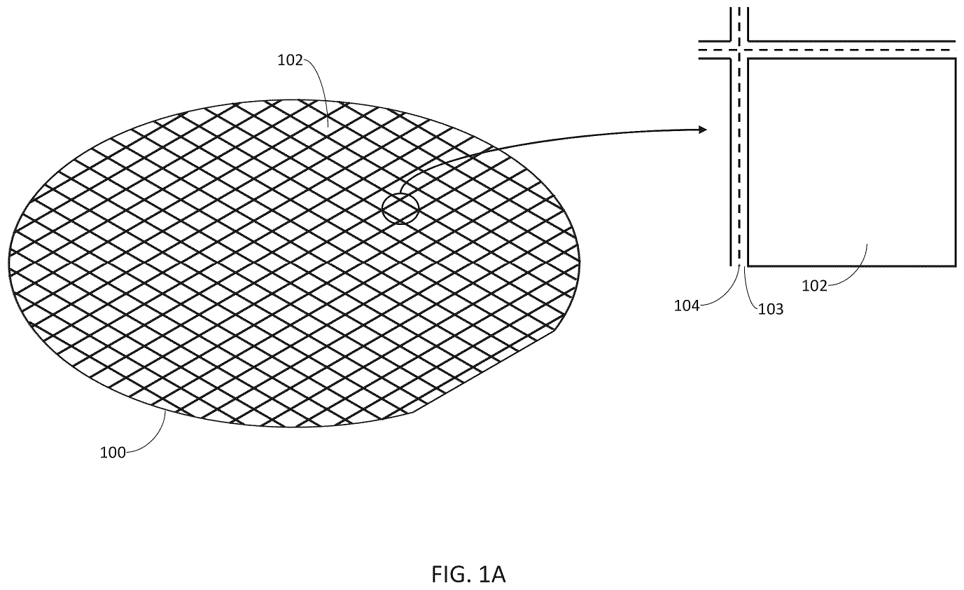

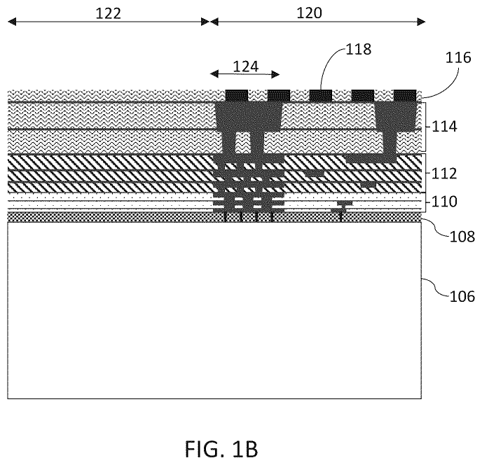

FIG. 1A illustrates an example of a wafer 100 comprising a plurality of devices 102 prior to dicing. The devices 102, including active regions, can be separated from each other by separating regions 103 (also referred to as scribe region herein). The separating regions 103 can overlap or encompass the devices' exclusion zone, in which no active devices are formed. The separating regions 103 can include scribe lanes 104 (indicated by dashed lines), which are sometimes also referred to as saw streets when the singulation is to be performed by sawing. The scribe lane 104 can be, in some embodiments, an imaginary line or a physical groove or other marking within the separating region 103. The actual removed portion of the substrate removed during singulation or dicing need not exactly correspond to the scribe lane and may be slightly misaligned. In some embodiments, the area removed during singulation or dicing may be smaller than or larger than the scribe lane, but generally will be less than or the same as the width of the separating region. In some embodiments, a scribe region can be about as wide as a saw width, although in some embodiments the scribe region can be substantially wider than a width that is used for sawing or other singulation methods. Depending upon the particular dicing method, the scribe region width could be in the range of about 1-100 nm for example for plasma dicing, or 10-1000 μm for saw dicing. The wafer 100 can be separated or singulated into a plurality of individual dies for each device 102 by separating the wafer along the scribe lanes 104, for example via blade sawing, etching, laser dicing, or other methods known in the art. As will be discussed in more detail below, singulation can be a source of debris. Debris may be especially problematic for dies that use low-k and/or ultra-low-k dielectric materials, which tend to be relatively brittle and to produce significant debris when diced.

FIG. 1B illustrates a side view of part of a wafer near a scribe lane. As shown in FIG. 1B, a wafer can include a substrate 106, a transistor layer 108 in the substrate 106, local interconnect levels 110, intermediate interconnect levels 112, and global interconnect levels 114. In some embodiments, a top layer 116 can be a direct bonding (DBI) layer having interconnects 118. The wafer can have a device region 120 and a scribe lane region 122. In some embodiments, one or more edges of the device region 120 can include a die edge seal 124. In some embodiments, the local interconnect levels 110 can comprise one or more low-k and/or ultra-low-k dielectric materials. In some embodiments, the intermediate interconnect levels 112 can comprise one or more low-k and/or ultra-low-k dielectric materials. In some embodiments, the global interconnect levels 114 can comprise one or more dielectric materials with relatively high dielectric constants, such as silicon dioxide or fluorosilicate glass (FSG). While not explicitly labeled in other drawings, it will be appreciated that the device structures described herein can have levels that are similar to or the same as those depicted in FIG. 1B.

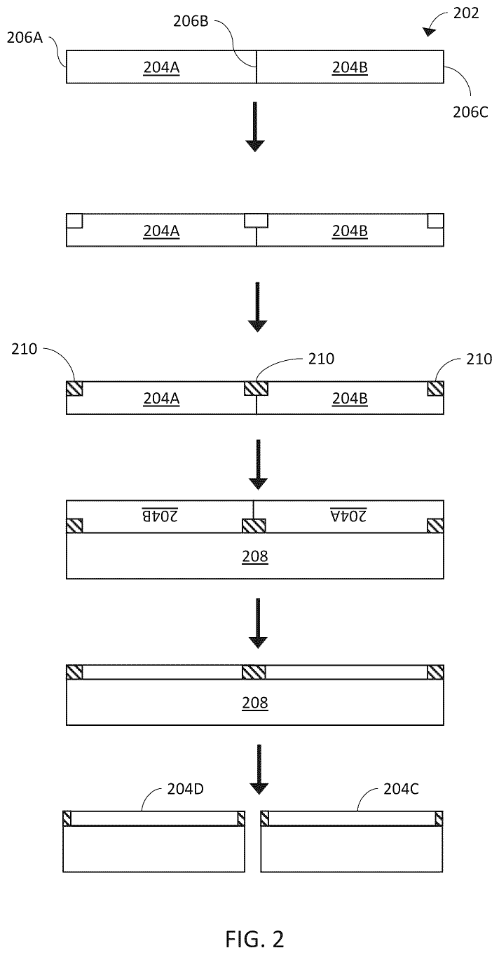

FIG. 2 illustrates an example dielectric fill and bonding process. A wafer 202 can comprise devices 204A and 204B that are to be singulated to form dies. The wafer 202 can have scribe lanes 206A-206C between and at the edges of the devices 204A and 204B. Separating regions encompassing and in some cases wider than scribe lanes 206A-206C on the front or active side of the die can be etched (e.g., plasma or dry etched) or laser grooved, leaving voids in the form of blind holes, trenches, channels, or cavities. The voids can be filled with a fill material 210, which can be a dielectric material (e.g., silicon oxide or another suitable dielectric material). In embodiments, the dielectric material 210 is less susceptible to splintering, flaking or delamination compared to some low-k materials at the front side of the devices 204A, 204B. The wafer 202 can then be flipped and bonded (e.g., directly bonded, such as by hybrid direct bonding) to a carrier wafer 208. After bonding, the backside of the wafer 202 can be thinned by backgrinding and/or polishing (e.g., using chemical mechanical polishing), which can expose the dielectric material 210 and reveal other components of the devices 204A and 204B, such as through silicon vias (TSVs). When the devices 204A and 204B are separated by such combination of the thinning and the prior formation of the dielectric-filled cavities, the subsequent sawing or other singulation technique to form dies 204C and 204D can be significantly cleaner, reducing particle contamination, can be less prone to cracking, can be less susceptible to delaminations at the edges, and so forth.

A plasma or dry etching process, or laser etching, followed by a dielectric trench fill can have several advantages over some other singulation approaches, such as laser grooving followed by sawing. The material for filling the trench can have a different structure and/or different chemical composition than one or more interlayer or interlevel (ILD) materials used in the interconnect levels. The dielectric trench fill (e.g., to replace the interlayer or interlevel dielectric (ILD) materials in the interconnect levels, which can include low-k and ultra-low-k material with a material with improved mechanical strength such as a higher-k dielectric) can help to protect the low-k and ultra-low-k material at the die edges during singulation, which can reduce the likelihood of cracks and other defects forming in the low-k and/or ultra-low-k materials, as well as limiting the production of debris from the low-k and/or ultra-low-k materials during singulation. In some embodiments, rather than filling the trench with a higher-k dielectric material, the trench can be filled with another material that is more resistant to cracking, flaking, etc., than the low-k and/or ultra-low-k dielectrics used in the interconnect levels. Such a material can be, for example, a polymer that is more resistant to cracking, flaking, etc., without necessarily having a higher dielectric constant. In some embodiments, depending upon the interlayer or interlevel dielectrics being replaced, trench fill materials can include dielectric materials such as silicon oxide, silicon nitride, and silicon oxynitride and/or non-dielectric materials such as, for example, spin-on-carbon, amorphous carbon, amorphous silicon, polysilicon, epitaxial silicon, and so forth. In some embodiments, a polymeric dielectric can include benzocyclobutene, polyimides, and polybenzoxazoles. In some implementations, polymeric dielectrics may be desirable; however, in other implementations, polymeric dielectrics may be undesirable, for example for some bonding processes. In some processes, sawing to singulate the devices into separate dies can be avoided because the dies become singulated by the thinning process (and, for example, subsequent processing to remove the trench fill material), but as will be appreciated from further disclosure below, the refilled voids can be advantageous even when combined with subsequent conventional singulation, such as sawing.

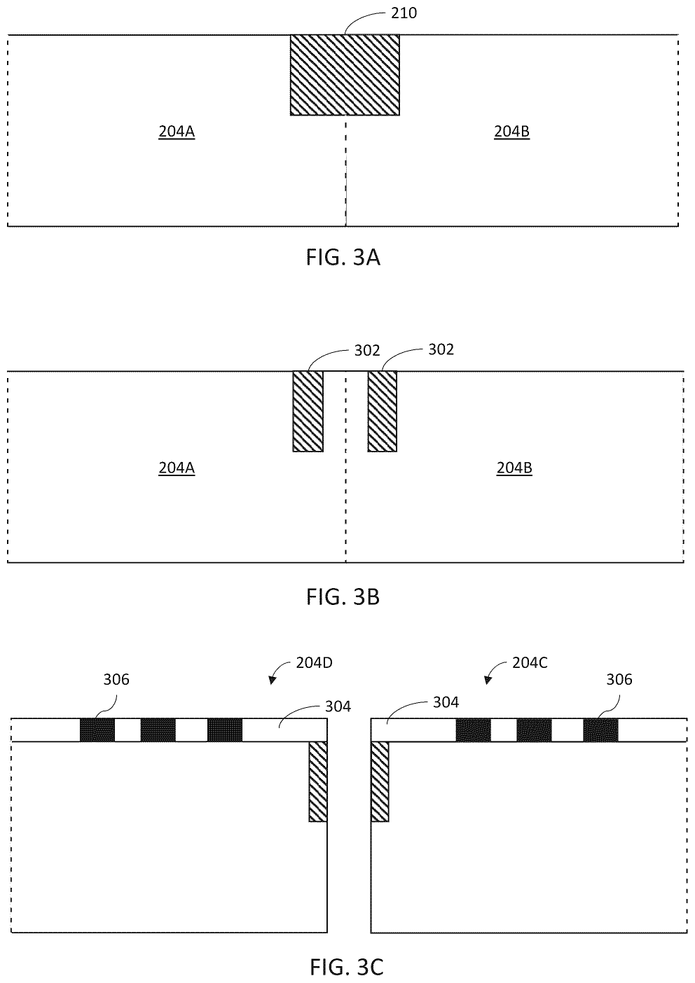

Various approaches can be used to prepare a wafer for singulation. In some embodiments, a void that encompasses or spans a scribe lane or separating region can be filled with dielectric as shown in FIGS. 2 and 3A (dielectric material 210). In some embodiments, instead of spanning the separating region, narrower trenches can be etched and filled with dielectric 302, as shown in FIG. 3B, while leaving some of the original material in place near the center of the separating region (which can include the scribe lane). The approach illustrated in FIG. 3B can have several advantages. For example, by etching less material, throughput may be increased, material (e.g., reactant) usage can be decreased, and so forth.

In some embodiments, a process can include frontside and backside etching steps. For example, a frontside etching step can include etching a distance into one or more materials (e.g., dielectric materials). In some embodiments, a substrate can also be etched from the backside, which can be an exposed semiconductor bulk substrate or can also include dielectric materials. In some embodiments, the substrate can be thinned (e.g., by backgrinding and/or polishing) prior to etching. Such an approach may be beneficial to optimize etching processes and/or for controlling stresses in a wafer during wafer bonding and/or thinning steps.

Backfilling an etched region with a dielectric (e.g., silicon oxide, polymer dielectric, etc.) can be advantageous. For example, backfilling with an oxide or other dielectric material can help to control stresses in the wafer during further processing (e.g., singulation), can reinforce the low-k and ultra-low-k layers, and/or can reduce singulation debris that can be detrimental to direct bonding (e.g., direct hybrid bonding) processes and other processing steps. In some embodiments, a buffer dielectric (e.g., oxide) can be deposited on the front surface of the wafer after trench filling, which may further help to control stresses in the wafer. For example, a front surface dielectric (e.g., silicon oxide) layer can be about 3 μm to about 10 μm thick, or even more if desired. The front surface dielectric layer can be provided as a direct bonding layer, and in some embodiments can include embedded conductors for direct hybrid bonding.

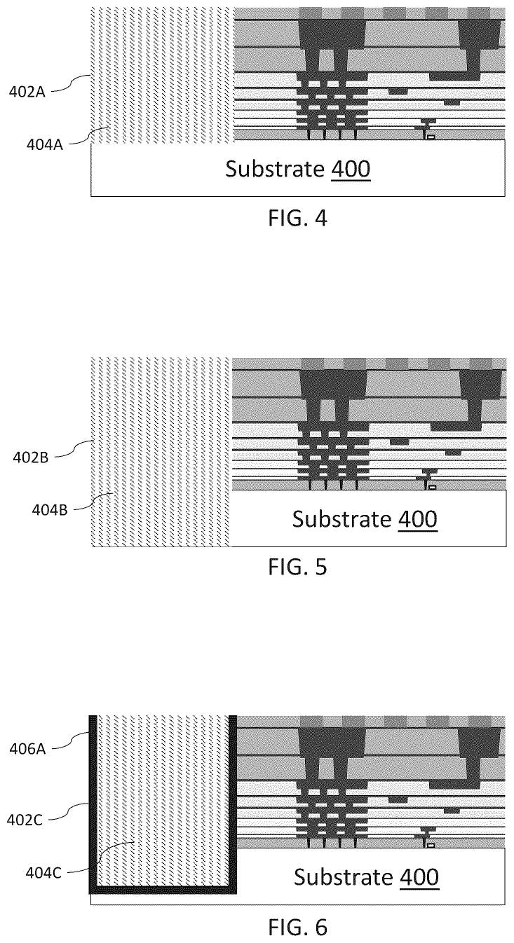

FIG. 3C illustrates the wafer of FIG. 3A or FIG. 3B after providing a direct hybrid bonding (e.g., DBI) layer 304, including embedded conductors 306 to serve as bonding pads, over the wafer and dicing to leave two dies 204C and 204D. The bonding layer shown in FIG. 3C and in the following figures can include both an inorganic dielectric and conductors. A bonding layer can be treated (e.g., polished, activated, terminated, etc.) as described below for direct hybrid bonding. A bonding layer can be formed after the formation of the filler dielectric and can overlie the filler dielectric as shown in FIG. 3C, or the bonding layer can be formed before the filler dielectric, for example as shown in FIGS. 4-11.

FIGS. 4-11 illustrate various embodiments of semiconductor devices or wafers with backfilled dielectrics (e.g., oxides). FIGS. 4-11 may also depict the edge of the die after singulation. In FIG. 4, a void 402A can be etched through all layers of the device and can stop at or near the surface of the substrate 400. The void 402A can be filled with dielectric material 404A. Although FIG. 4 shows a single dielectric material 404A, it may be deposited in multiple deposition steps. In some embodiments, each dielectric deposition step (e.g., of silicon oxide) can be followed by another dielectric layer (e.g., a thin layer of silicon nitride). Such a layered approach may aid in stress balancing. In some embodiments, the dielectric material 404A can be an insulating material, organic or inorganic material, combination of organic and inorganic materials, a protective material, any combination of these materials, and so forth. In some embodiments, the etch process may not stop at the substrate surface. For example, as shown in FIG. 5, a void 402B can be etched extending into the substrate 400 (e.g., partially through the substrate 400 or all the way through the substrate 400) and filled with dielectric material 404B.

As shown in FIG. 6, in some embodiments, the void 402C can be filled with multiple materials. For example, as shown, an intermediate layer 406A can be formed in the void 402C after etching. and before filling with a different filler dielectric material 404C. In some embodiments, the intermediate layer 406A is conductive; in some embodiments, the intermediate layer 406A is another dielectric. In some embodiments, the intermediate layer can be a liner layer such as a nitride layer (e.g., TiN, TaN, SiN, SiON, SiCN, SiCON, SiBCN, and so forth), a carbide layer (e.g., SiC), an adhesion layer, and so forth. An intermediate layer can be employed for a variety of reasons. For example, the intermediate layer 406A can act as an adhesion layer to prevent the filler dielectric material 404C from separating from the substrate 400 and/or from other layers in the die. In some embodiments, the intermediate layer 406A can have a thickness of from about 10 nm to about 200 nm, such as from about 20 nm to about 50 nm. Although only one intermediate layer is depicted in FIG. 6, it is understood that two or more such layers may also be used.

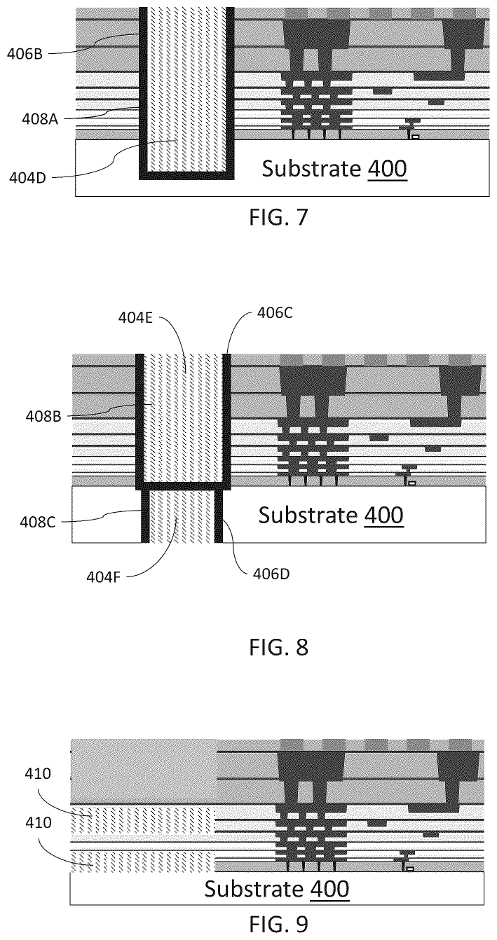

FIG. 7 depicts another example embodiment that is broadly similar to FIG. 6. In contrast to FIG. 6, FIG. 7 shows a relatively narrow trench 408A that is filled with dielectric material 404D. As shown in FIG. 7, the trench 408A has an intermediate layer 406B, although in some embodiments an intermediate layer may not be used. The trench 408A can be substantially narrower than the width of a corresponding separating region. For example, the trench 408A may be used in a process similar to the approach discussed above with reference to FIG. 3B.

FIG. 8 shows an example embodiment having two trenches that are separately filled to span the wafer thickness. A first trench 408B can have a first depth. For example, the first trench 408B can extend from the top surface to the surface of the substrate 400. The first trench can be lined with a first intermediate layer 406C and filled with a first dielectric material 404E. A second trench 408C can be formed from the backside (e.g., starting from an exposed surface of the substrate 400 or any backside layers). The second trench 408C can extend a second depth. For example, the second trench 408C can extend to the bottom of the filled first trench 408B as shown. The second trench 408C can be lined with a second intermediate layer 406D and filled with a second dielectric material 404F. In some embodiments, the first trench 408B and second trench 408C may meet, for example at the surface of the substrate 400, although this need not be the case. Likewise, in some embodiments, the first trench 408B and second trench 408C can have the same width, while in other embodiments, the first trench 408B and second trench 408C can have different widths as shown. In some embodiments, the second trench 408C can be formed from the frontside, for example by forming a deep trench and partially filling it with the second dielectric material 404F (and, optionally, the second intermediate layer 406D) to define second trench 408C, followed by depositing the first dielectric material 404E (and, optionally, the first intermediate layer 406C) to define the first trench 408B.

As shown in FIG. 9, in some embodiments, only some layers may be replaced in or near a scribe lane or separating region. For example, in some embodiments, low-k and/or ultra-low-k dielectrics can be formed in an active device region as shown at the right side of FIG. 9, while the regions 410 spanning or at the edges of the scribe regions can have another dielectric (e.g., silicon dioxide) that is less susceptible to cracking, delamination, and other issues formed therein. In some embodiments, multiple dielectric layers can be deposited or otherwise formed in the scribe region. In one such embodiment, one or more low-k or ultra low-k layers may be removed within the separating region (e.g., after wafer level deposition of the one or more layers) and replaced by one or more dielectric layers or protective layers. For example, after deposition of one or more ultra low-k layers (and, optionally, metallization after each layer deposition) on the wafer, material can be removed (for example by etching) near or overlapping the scribe lanes and replaced by a first dielectric or other protective material. In some embodiments, this can be followed by the wafer-level deposition of one or more low-k layers (and, optionally, metallization). The low-k layers can be removed (e.g., by etching) near or overlapping the scribe lanes and replaced by a second dielectric or protective material. Such an approach may offer several benefits, such as reducing deposition time by limiting the dielectric thicknesses, limiting problems that can occur when filling deep trenches such as the formation of gaps or voids, stresses, and so forth, which can compromise the reliability, electrical properties, thermal properties, and so forth of the material, providing the higher-k filler dielectric material only where needed at the same time level as the interconnects are being patterned and surrounded by low-k materials, and so forth. Such an approach may help to prevent the propagation of defects resulting from a singulation process into the active device region. In some embodiments, debris production may present problems when such an approach is used. Debris production can present challenges for later steps, such as direct bonding. Additionally, the structure in FIG. 9 can use other processing steps. For example, multiple patterning steps, deposition steps, and so forth may be used when selectively forming dielectrics in multiple regions or multiple layers.

The examples above depict the formation of a fill material (e.g., filler dielectric) in a separating region in or near the scribe lanes of a wafer containing a plurality of dies. However, in some embodiments, oxides or other higher-k dielectrics or protective dielectrics may selectively replace low-k and/or ultra-low-k dielectrics in some parts of active device regions in addition or instead. As shown in FIG. 10, dielectric regions 1002 can be selectively disposed through the active device region. The regions 1002 can comprise relatively high-k materials (e.g., high-k relative to other nearby dielectrics at the same interconnect levels). The regions 1002 can act as arrestors that prevent the propagation of defects, cracks, and/or delamination through one or more layers of the semiconductor device. For example, arrestors may be formed near critical components or interconnects so that a device can continue to function even if cracks or other defects form in other areas within the device. In some embodiments, an arrestor can be formed a few micrometers from a critical component or interconnect, for example about 10 micrometers or less or about 1 micrometer or less, or from about 1 micrometer to about 10 micrometers. In some embodiments, arrestors can be distributed throughout a die. Cracks typically form within a tens of micrometers from the edge of the die. Accordingly, in some embodiments, arrestors can be disposed near critical components or interconnects that are near the edge of the die. FIG. 10 also shows higher-k filler dielectrics in the separation region 1006 adjacent to interconnect levels that include low-k materials to alleviate the delamination and flaking issues described above from singulation, although some implementations may not use higher-k dielectrics in the scribe regions.

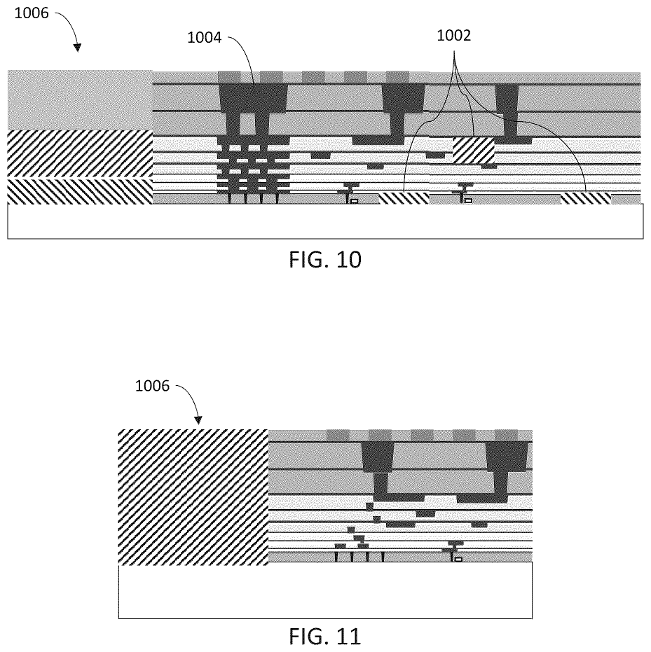

Further, as shown in FIG. 10, a die can include a metal seal ring 1004 near the separating region 1006. The metal seal ring 1004 can help to arrest cracks, delamination, and other defects that form during a singulation process or during device operation (e.g., due to thermomechanical stresses). However, not all device dies may include a metal seal ring 1004. For example, the device shown in FIG. 11 does not include a metal seal ring. Various structures shown in FIGS. 4-11 may act as crack arrestors, hermetic seals, etc., in the absence of such dedicated metal seal ring, or even when a metal seal ring is present.

Even if a semiconductor device does have such a metal seal ring to stop the propagation of cracks, it may still be desirable to deposit a filler dielectric layer, which may serve as a protective layer. For example, in the case of copper interconnections, a crack that propagates to the metal seal can result in a path for oxidation of the metal, which can result in an undesirable expansion of the metal layers and damage to the semiconductor device. Accordingly, FIGS. 10 and 11 both also show higher-k filler dielectrics in the separating regions 1006 adjacent to interconnect levels that include low-k materials to minimize delamination, cracking, and flaking issues described above from singulation. FIG. 10, like FIG. 9, shows higher-k filler dielectrics formed in layers at the same level of interconnect levels that include low-k dielectrics. In FIG. 11, the higher-k filler dielectric can be formed at the end of the process and vertically span multiple interconnect levels that include low-k materials.

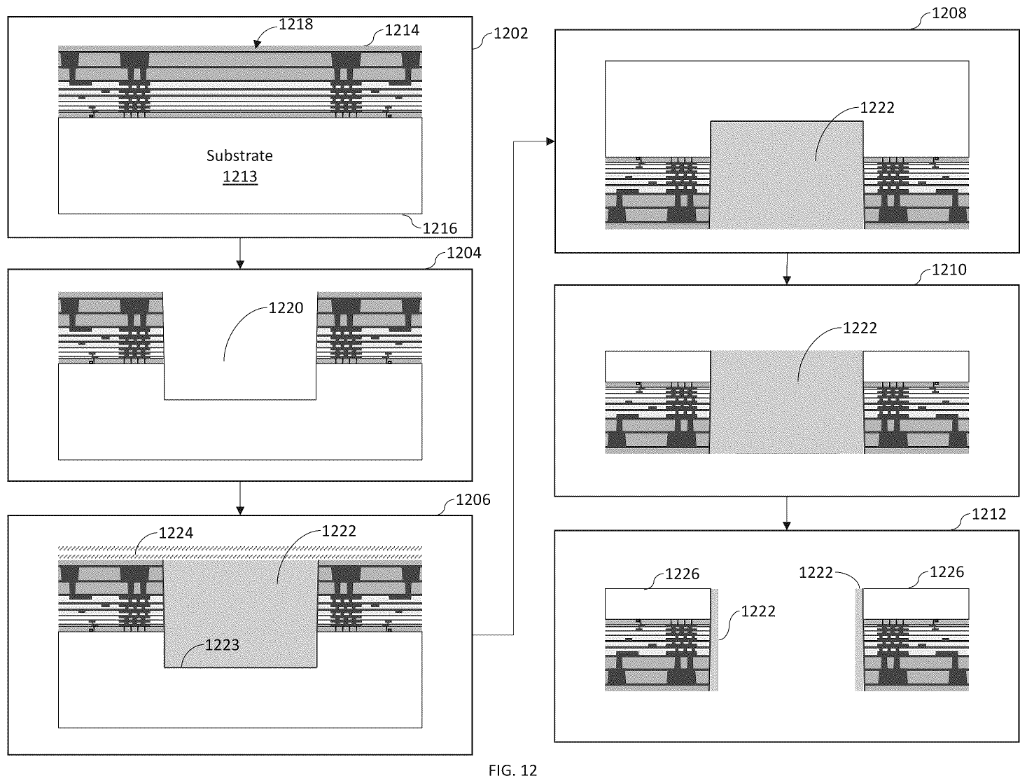

FIG. 12 illustrates an example process according to some embodiment. At block 1202, a wafer that includes many devices to be singulated into dies can include a substrate 1213, a top surface 1214, a bottom surface 1216, and a separating region 1218. At block 1204, portions of the separating region 1218 can be removed, for example etched away (e.g., via dry or plasma etching), the etching shown extending through metallization and device layers and into the substrate 1213 (e.g., bulk semiconductor material) to leave a trench 1220. At block 1206, the trench 1220 overlapping the separating region 1218 can be filled with a dielectric 1222 (e.g., silicon oxide). In some embodiments, the separating region 1218 trench 1220 can be filled with a dielectric 1222 in a single deposition step or in multiple deposition steps. In some embodiments, one or more buffer layers 1223 comprising, e.g., TiN, TaN, SiN, SiON, SiCN, SiCON, SiBCN, or another suitable material can be deposited before the dielectric 1222 to line the trench 1220. In some embodiments, a top buffer layer 1224 (e.g., silicon oxide) can be deposited on a top surface (e.g., after a chemical mechanical polishing (CMP) step to remove overburden from the dielectric 1222 deposition). In some embodiments, the buffer layer may also be used as a bonding layer or as a part of the bonding layer and thus can form part of a direct bonding interface. At block 1208, the structure can be flipped and at block 1210 the bottom surface 1216 can be polished to remove part of the substrate 1213 and to expose the dielectric 1222, resulting in the structure shown at block 1210 in which the individual devices to be singulated into dies are joined by the dielectric 1222 but not by the substrate 1213. At block 1212, the dies 1226 can be singulated through dicing (sawing, laser etching, etc.) through the filler dielectric 1222 such that the entire vertical edges of the dies 1226 are formed by the filler dielectric 1222. For multistep deposition processes, vertical edges of the dies 1226 can be formed by two or more layers of the filler dielectric 1222, which may itself be formed with layers of two or more materials, as explained above with reference to FIG. 4.

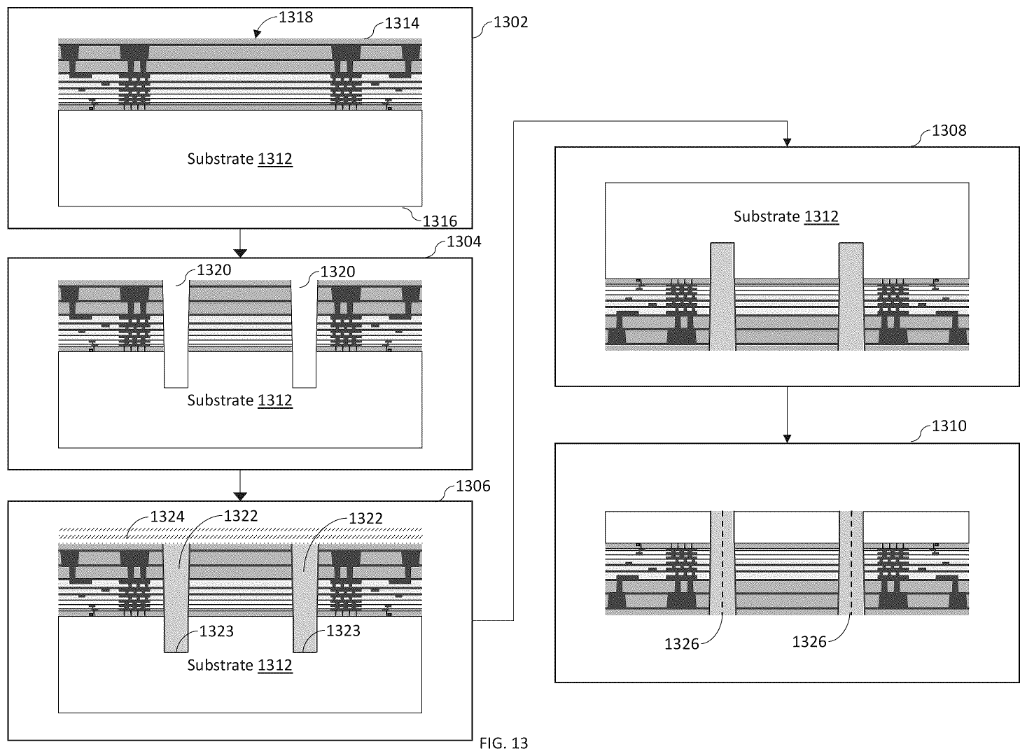

FIG. 13 illustrates an example process according to some embodiments. At block 1302, a wafer comprising a plurality of devices to be singulated into dies can include a substrate 1312, a top surface 1314, a bottom surface 1316, and a separating region 1318. At block 1304, trenches 1320 can be etched or otherwise formed into the structure in the separating region 1318. As shown in FIG. 13, the trenches 1320 can be disposed near the sides of the separating region 1318, while the middle portion of the separating region 1318 can remain intact. As discussed above, leaving part of the separating region 1318 intact can improve etching throughput, reduce etchant consumption, reduce particle generation, and so forth as less material is removed from the structure. At block 1306, the trenches 1320 can be filed with dielectric 1322. In some embodiments, a buffer layer 1323 (e.g., TiN, TaN, SiN, SiON, SiCN, SiCON, SiBCN, or another suitable material) can be formed into the trenches 1320 prior to forming the dielectric 1322. In some embodiments, a top buffer layer 1324 (e.g., silicon oxide) can be formed on the top surface 1314, for example after a polishing step to remove overburden from the dielectric 1322 deposition. At block 1308, the structure can be flipped and at block 1310 the bottom surface 1316 can be polished or otherwise thinned to remove part of the substrate 1312 to form the structure at block 1310 in which the dielectric 1322 is exposed and individual dies are no longer joined by the substrate 1312. The wafer may subsequently be singulated, for example by sawing or other dicing methods, thereby separating the devices into individual dies along lines 1326. Cracks or defects that may form in the remaining part of the separating region 1318 can be arrested by the dielectric 1322 so that they do not propagate into the device dies. While the lines 1326 representing the edges of the singulation cuts are depicted as passing through the trenches 1320, it will be appreciated that when singulating the die, the saw, laser, or other dicing device may dice through the material between the trenches 1320 without contacting the dielectric 1322. In some embodiments, dicing may result in contact with one or both of the trenches 1320.

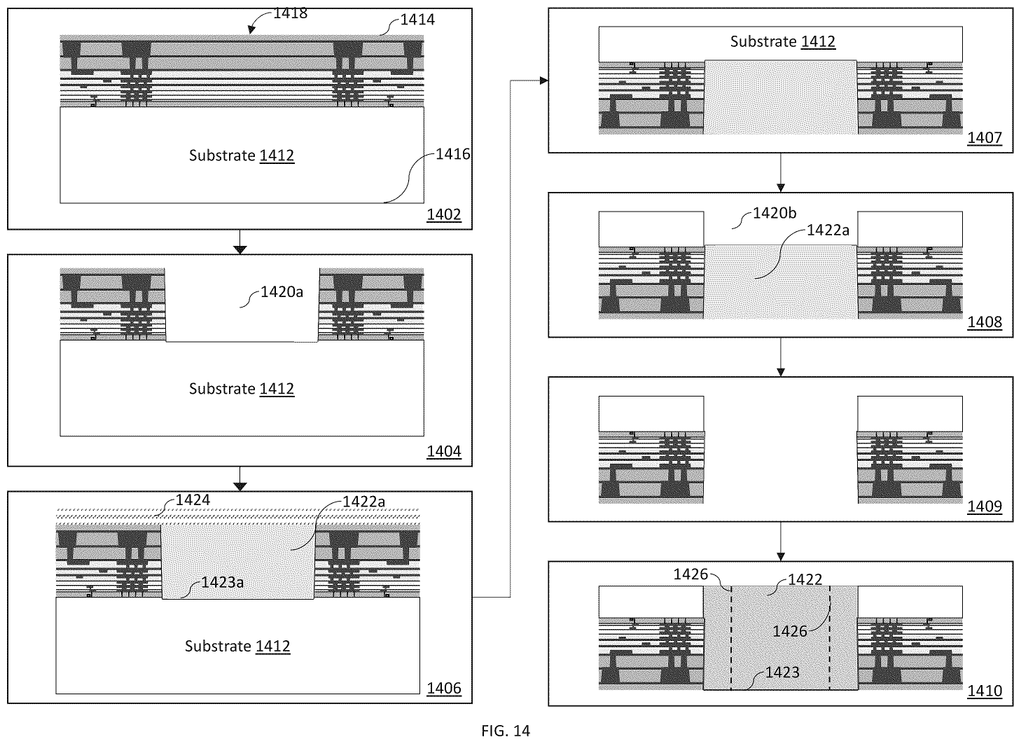

FIG. 14 illustrates another example process according to some embodiments. At block 1402, a structure can have a substrate 1412 and a plurality of devices to be singulated into dies formed therein. The devices to become dies can be separated by a scribe region 1418. The structure can have a top surface 1414 and a bottom surface 1416. At block 1404, the scribe region 1418 can be etched or otherwise partially removed to form trenches 1420a, and the etch can stop at or near the surface of the substrate 1412. At block 1406, a sacrificial fill 1422a can be deposited. In some implementations, the sacrificial fill 1422a can fill the trenches 1420a relatively easily, can be easily planarized, and can be easily selectively removed. In some embodiments, the sacrificial fill 1422a can comprise spin-on-carbon, a bottom anti-reflective coating (BARC) (e.g., as may be used in photolithography process), or another suitable material. In some embodiments, a first buffer layer 1423a may be formed before the sacrificial fill 1422a. A buffer layer 1424 can be deposited on top of the sacrificial fill 1422a and the devices. At block 1407, the structure can be flipped and the substrate 1412 can be thinned. At block 1408, a trench 1420b can be etched through the substrate 1412 to expose the sacrificial fill 1422a. At block 1409, the sacrificial fill 1422a can be removed and, at block 1410, a dielectric 1422 can be formed between the devices to be singulated into dies. For example, the devices can be singular by sawing or other methods such that the devices are separated along lines 1426. In some embodiments, a second buffer layer 1423 may be formed before the dielectric 1422. In some embodiments, the first buffer layer 1423a may remain after the sacrificial fill 1422a is removed. In some embodiments, the second buffer layer 1423 may be the first buffer layer 1423a.

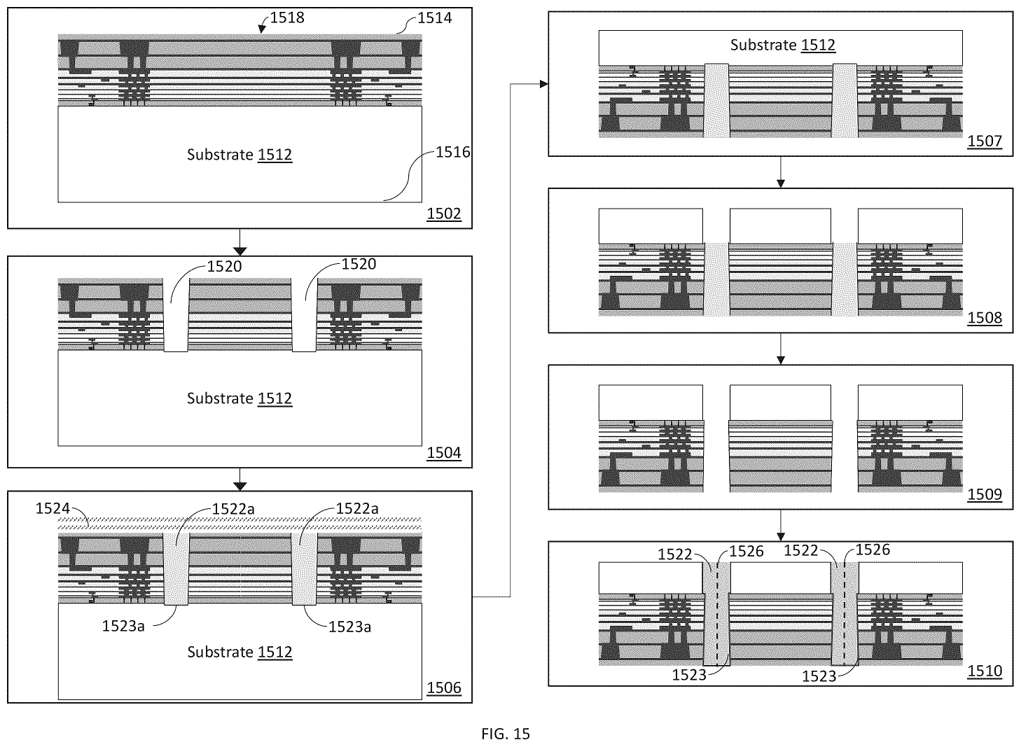

FIG. 15 illustrates an example process according to some embodiments. The process illustrated in FIG. 14 is broadly similar to the process shown in FIG. 14. However, as with FIG. 13, rather than etching away an entire scribe region, two trenches near the edge of the scribe region can be etched and the material in the center of the scribe region can be left intact. As shown in FIG. 15, at block 1502, a structure can include a substrate 1512, a top surface 1514, a bottom surface 1516, and a scribe region 1518 disposed between two devices to be singulated into dies. At block 1504, two trenches 1520 can be formed in the scribe region 1518, leaving a center portion of the scribe region 1518. At block 1506, the two trenches 1520 can be filled will a sacrificial material 1522a. In some cases, an intermediate layer 1523a can be formed in the two trenches 1520 prior to the formation of the sacrificial material 1522a. A top buffer layer 1524 can be formed on the top surface 1514. At block 1507, the structure can be flipped and the substrate 1512 can be thinned, polished, and so forth. At block 1508, trenches can be formed in the substrate 1512 to extend the two trenches 1520 through the substrate 1512. At block 1509, the sacrificial material 1522a can be removed. As discussed above with respect to FIG. 15, the intermediate layer 1523a can also be removed or may remain in place along the vertical sides of the dies. At block 1510, the trenches can be filled with a dielectric 1522. The trenches can have a buffer layer or intermediate layer 1523 formed therein prior to the formation of the dielectric 1522. In some cases, the intermediate layer 1523 can be the same as the intermediate layer 1523a, while in other implementations, the intermediate layer 1523 can be different from the intermediate layer 1523a. The structure can then be singulated into individual dies, for example by separating the dies along the lines 1526. As discussed with respect to FIG. 13, when dicing, the saw, laser, etc., may contact one, both, or none of the trenches.

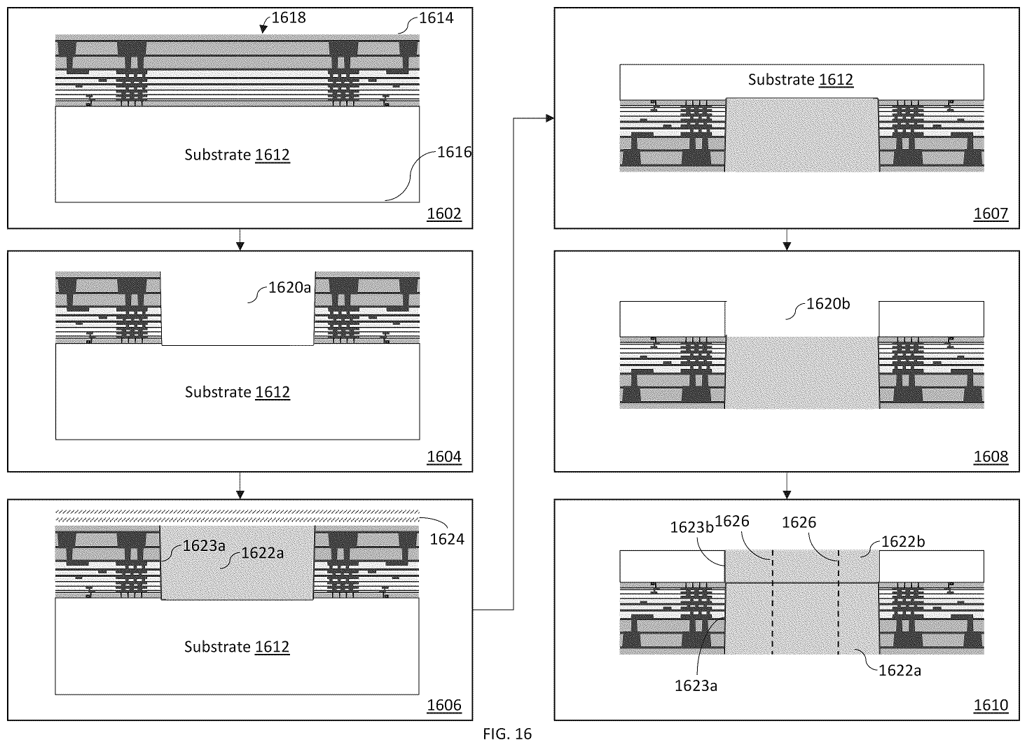

FIG. 16 illustrates another example process according to some embodiments. At block 1602, a structure can have a substrate 1612, a top surface 1614, a bottom surface 1616, and a scribe region 1618 disposed between device dies. At block 1604, the scribe region 1618 can be etched away down to the surface of the substrate 1612 to form a trench 1620a. At block 1606, the trench can be filled with a first dielectric 1622a. A first buffer layer 1623a can be formed in the trench before the formation of the first dielectric 1622a. A top buffer layer 1624 can be formed on the top surface 1614. At block 1607, the structure can be flipped and the substrate 1612 can be thinned. At block 1608, a portion of the substrate 1612 in the scribe region 1618 can be removed, for example by etching to form a second trench 1620b aligned with the first trench 1620a. At block 1610, the etched portion can be filled with a second dielectric material 1622b. A second buffer layer 1623b can be formed before the formation of the second dielectric material 1622b. The first dielectric 1622a and the second dielectric material 1622b can be the same material or can be different. The first buffer layer 1623a and second buffer layer 1623b can be the same or can be different. In some cases, the first buffer layer 1623a, the second buffer layer 1623b, or both may not be included. The structure can then be singulated into individual dies, for example by separating along the lines 1626 (e.g., by sawing through the region between the lines 1626).

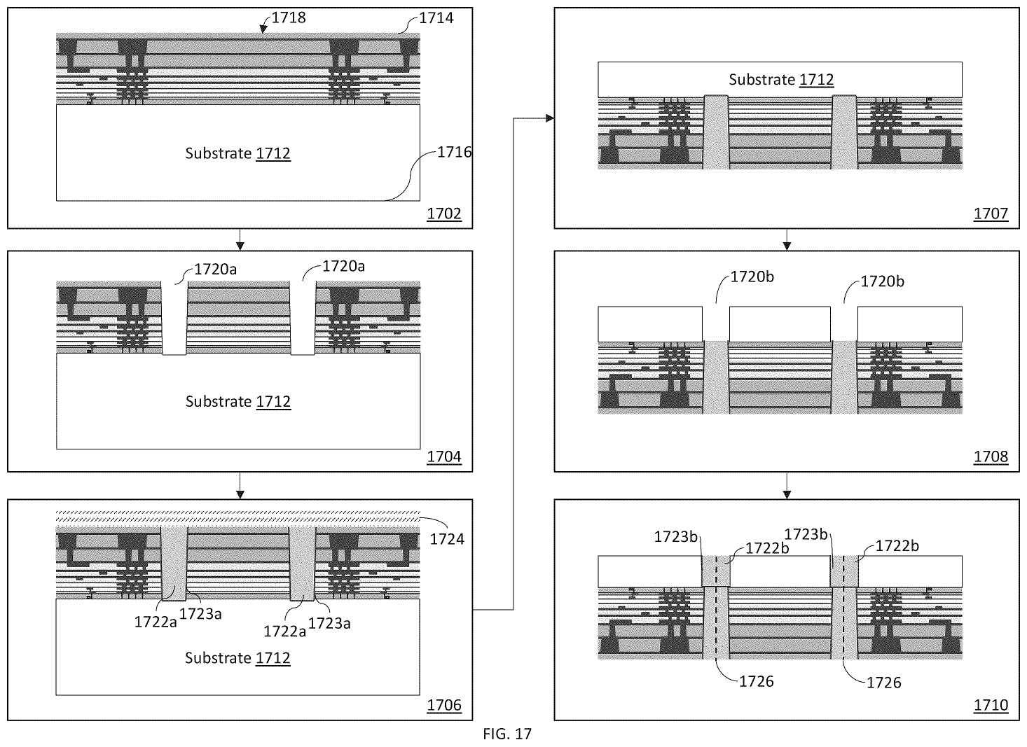

FIG. 17 illustrates another example process according to some embodiments. The process shown in FIG. 17 is substantially similar to the process shown in FIG. 16, except that rather than etching away the entire scribe region, trenches 1720a near the edges of the scribe region 1718 can be etched and the material in the center of the scribe region 1718 can be left intact. At block 1702, a structure can have a substrate 1712, a top surface 1714, a bottom surface 1716, and a scribe region 1718 located between device dies. At block 1704, first trenches 1720a can be etched or otherwise formed in the scribe region 1718, leaving a center portion of the scribe region 1718. At block 1706, the two trenches 1720a can be filled with dielectric 1722a. A first buffer layer 1723a can optionally be deposited in the trenches 1720a before forming the dielectric 1722a. Optionally, a top buffer layer 1724 can be formed on top of the trenches 1720a. At block 1707, the structure can be flipped and the substrate 1712 can be thinned, for example by polishing. At block 1708, second trenches 1720b can be formed in the substrate 1712 and can generally align with the first trenches 1720a. The trenches 1720b can generally have a width that is about the same as the width of the trenches 1720a. At block 1710, the second trenches 1720b can be filled with a second dielectric material 1722b. In some cases, a buffer layer 1723b can be formed in the second trenches 1720b before forming the dielectric material 1722b. As noted above, the dielectric materials 1722a, 1722b can be the same or different, but can both exhibit better resistance to flaking, delamination, etc. compared to lower-k materials in at least some of the interconnect layers that are replaced by the process. As in the examples above, the structure can be singulated to form individual dies along lines 1726, for example by sawing through the region between the lines 1726. As discussed with respect to FIG. 13 and FIG. 15 above, when dicing, the saw, laser, etc., may contact one, both, or none of the trenches.

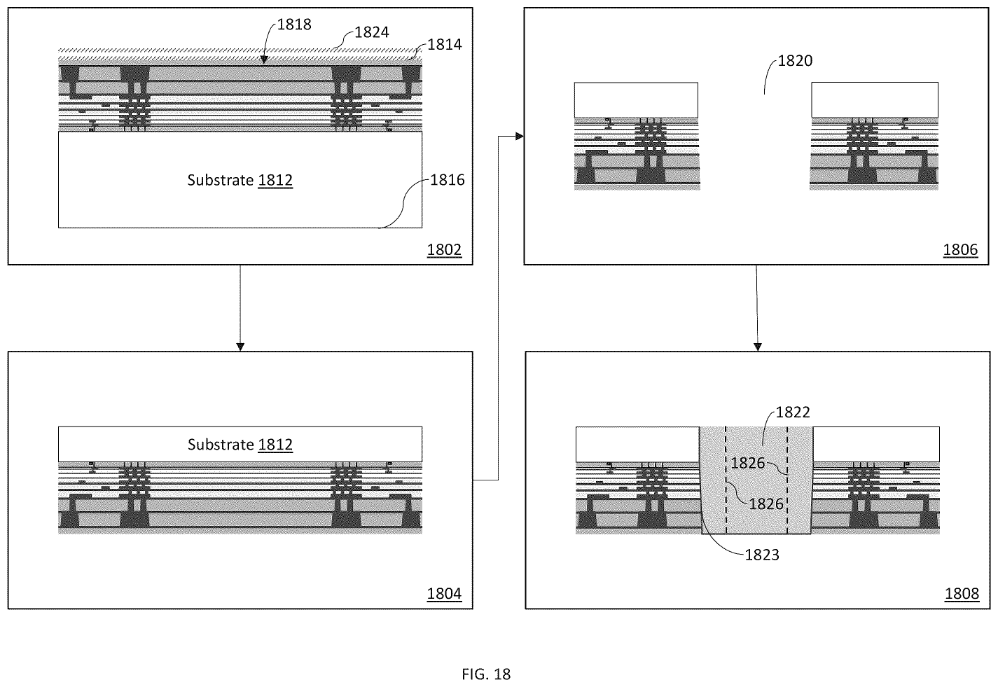

FIG. 18 illustrates another example process. As shown in FIG. 18, at block 1802, a structure can have a substrate 1812, a top surface 1814, a bottom surface 1816, a scribe region 1818, and a top buffer layer 1824 on top of the top surface 1814. At block 1804, the structure can be flipped and the substrate 1812 can be thinned, for example by a CMP process. At block 1806, the scribe region 1818 can be etched or otherwise processed to form a trench 1820 that extends through the entire wafer, including both the interconnect levels and the bulk substrate 1812. Depending upon the specific implementation, the trench 1820 can be formed (e.g., by etching) from the frontside of the wafer or the thinned backside of the wafer. At block 1808, the trench 1820 can be filled with a dielectric material 1822. In some cases, a buffer layer 1823 may be formed in the trench 1820 prior to forming the dielectric material 1822. The structure can subsequently be singulated to form individual device dies, for example by sawing such that the dies are separated along lines 1826. While a top buffer layer 1824 is shown in FIG. 18, it will be appreciated that the top buffer layer 1824 may not be present in some implementations of the process depicted in FIG. 18.

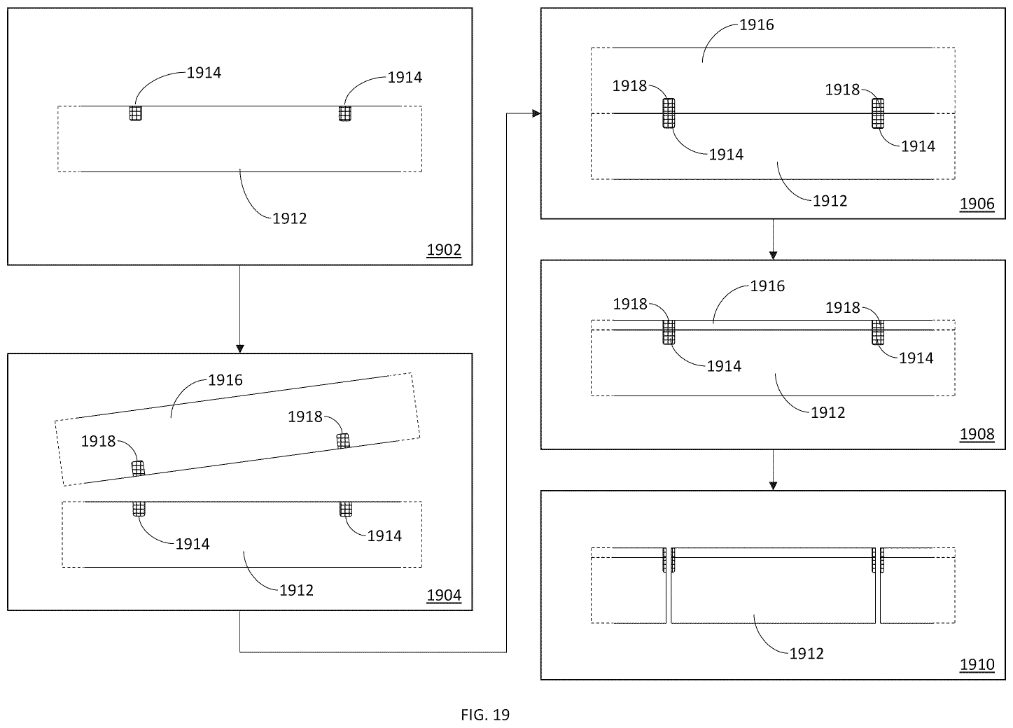

FIG. 19 illustrates an example process for direct bonding (e.g., direct hybrid bonding) wafers. At block 1902, a first wafer 1912 can have first scribe regions 1914 that have been etched and filled with a dielectric material having a higher dielectric constant than some of the surrounding low-k dielectrics used in active device regions of the first wafer 1912. The first scribe regions 1914 can separate devices to be singulated into dies. At block 1904, a second wafer 1916 having second scribe regions 1918 that are filled with relatively high-k dielectric material can be flipped onto the first wafer 1912. At block 1906, a top surface of the first wafer 1912 and a top surface of the second wafer 1916 can be brought into contact with each other and directly bonded. As will be understood by the skilled artisan in view of the disclosure herein, the upper surfaces of both wafers 1912, 1916 can include bonding layers, at least one of which is prepared (e.g., polished, activated, terminated) for direct bonding, and the bonding layers may include embedded conductors for direct hybrid bonding. At block 1908, the second wafer 1916 can be thinned, thereby exposing the second scribe regions 1918. At block 1910, the bonded structure (e.g., a combined structure including the first wafer 1912 and the second wafer 1916) can be singulated to form a plurality of dies by cutting, sawing, or otherwise separating the device dies. A singulation process can include cutting or etching through the first scribe regions 1914 and the second scribe regions 1918 as shown.

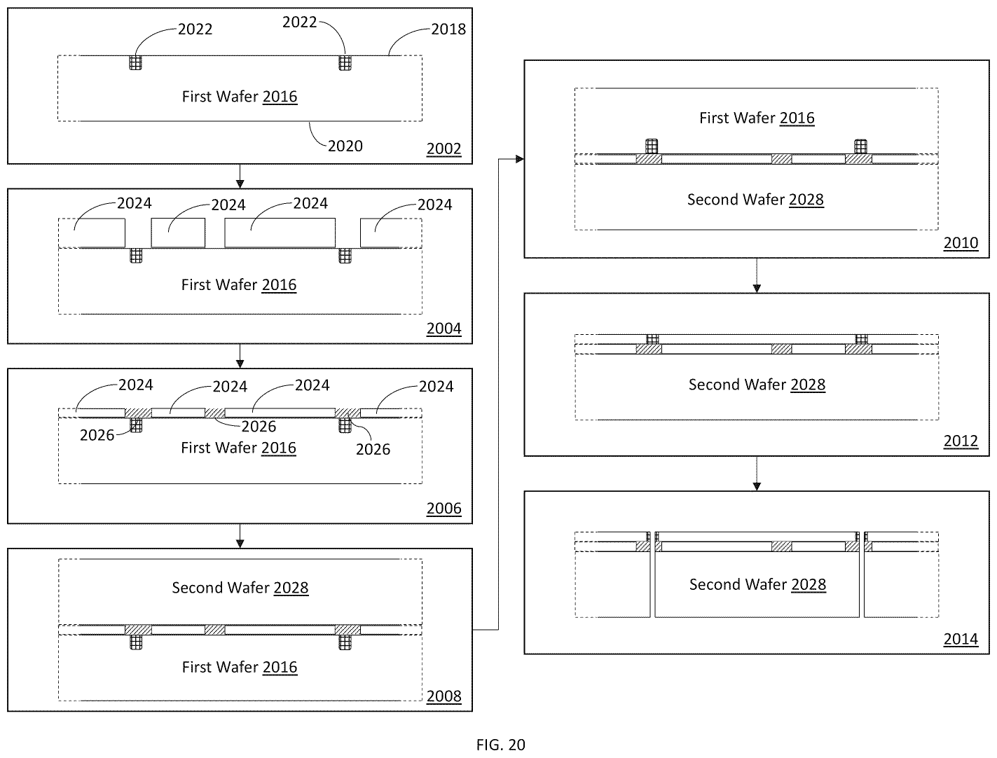

FIG. 20 illustrates another example process. While FIG. 19 illustrates a process involving direct bonding of wafers (W2W bonding), FIG. 20 illustrates die bonding (D2W bonding). At block 2002, a first wafer 2016 can have a top surface 2018 and a bottom surface 2020. The top surface 2018 can include trenches 2022 filled with a relatively high-k dielectric material (e.g., silicon oxide) compared to some of the lower-k materials employed in adjacent interconnect levels. At block 2004, a plurality of dies 2024 can be directly bonded (e.g., hybrid direct bonded) to the top surface 2018 of the first wafer 2016. In some embodiments, the plurality of dies 2024 can be thinned prior to singulation from their wafer and subsequent bonding to the first wafer 2016. At block 2006, the dies 2024 can be thinned and gaps between the dies can be filled with a gap-fill material 2026, which can be insulating, and then polished. In some embodiments, a reconstituted wafer comprising plurality of dies 2024 can be formed on the first wafer 2016. At block 2008, a second wafer 2028 can be bonded (e.g., directly bonded) on top of the dies 2024. At block 2010, the assembly can be flipped. At block 2012, the first wafer 2016 can be thinned, for example by grinding and/or polishing, revealing the dielectric-filled regions 2022. At block 2014, the structure can be singulated into a plurality of semiconductor device dies. In some embodiments, the second wafer 2028 can be included in the final semiconductor devices. In other embodiments, all or part of the second wafer 2028 can be a sacrificial carrier removed in other processing steps.

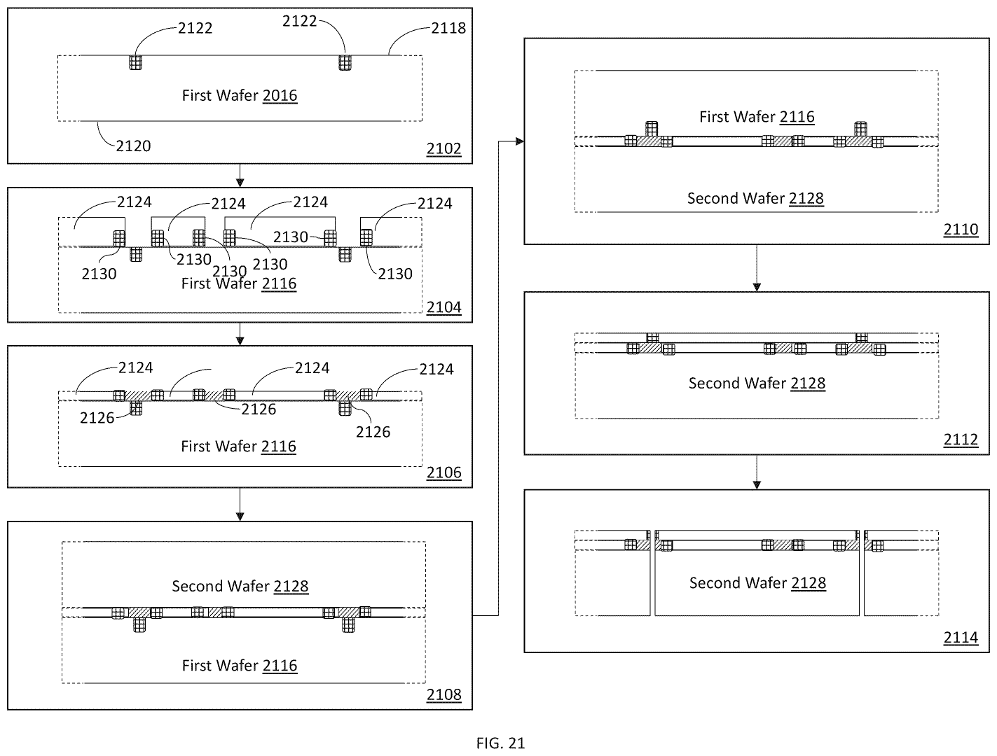

FIG. 21 depicts another example process. The process shown in FIG. 21 can be substantially similar to the process shown in FIG. 20. However, in FIG. 21, the dies 2124 can include a dielectric material 2130 (e.g., silicon oxide) on the edges of each die. Such a configuration may be desirable if, for example, the dies 2124 include low-k and/or ultra-low-k dielectrics. In such cases, the dies 2124 may have been prepared in earlier processing steps by etching the scribe lanes and depositing oxide into the scribe lanes as described in embodiments hereinabove prior to dicing.

At block 2102, a first wafer 2016 can have a top surface 2118 and a bottom surface 2120. The top surface 2118 can include trenches 2122 filled with a relatively high-k dielectric material (e.g., silicon oxide) compared to some of the lower-k materials employed in adjacent interconnect levels. At block 2104, a plurality of dies 2124 formed, for example, by the processes of any of FIGS. 12-18, can be directly bonded (e.g., hybrid direct bonded) to the top surface 2118 of the first wafer 2116. At block 2106, the dies 2124 can be thinned, for example by filling gaps between the dies 2124 with a gap-fill material 2126, which can be insulating, and then polishing. At block 2108, a second wafer 2128 can be bonded (e.g., directly bonded) on top of the dies 2124. At block 2110, the structure can be flipped and the first wafer 2116 can be thinned at block 2112, for example by grinding and/or polishing, revealing the dielectric-filled regions 2122. At block 2114, the structure can be singulated into a plurality of semiconductor devices, each of which include bonded stacks. In some embodiments, the second wafer 2128 can be included in the final semiconductor devices. In other embodiments, all or part of the second wafer 2128 can be sacrificial can be removed in other processing steps.

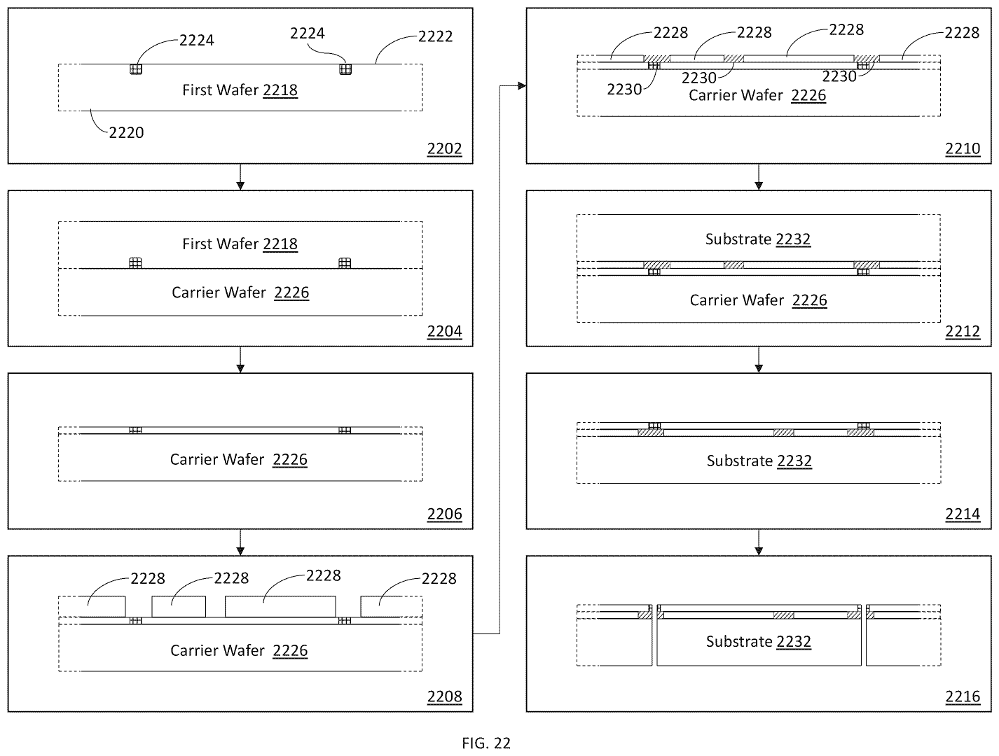

FIG. 22 depicts an example process for die to wafer backside bonding. As shown in FIG. 22, at block 2202, a first wafer 2218 can have a bottom surface 2220 and a top surface 2222. The top surface 2222 can have a plurality of trenches 2224 that are filled with dielectric material (e.g., a relatively high-k dielectric material, such as silicon oxide, compared to some of the lower-k materials employed in adjacent interconnect levels). The trenches 2224 can separate a plurality of semiconductor devices to be singulated into dies. At block 2204, the first wafer 2218 can be flipped and bonded (e.g., directly bonded) to a carrier wafer 2226. At block 2206, the first wafer 2218 can be thinned to expose the dielectric filled trenches 2224. At block 2208, a plurality of dies 2228 can be bonded to the backside of thinned first wafer 2218. At block 2210, gaps between the dies 228 can be filled with a gap-filling material 2230, which can be insulating, and the dies 228 thinned. At block 2212, a substrate 2232 can be bonded to the thinned dies 2228. At block 2214, the structure can be flipped and the carrier wafer 2226 can be removed, exposing the top side of the first wafer 2218. At block 2216, the structure can be singulated to form a plurality of semiconductor device dies.

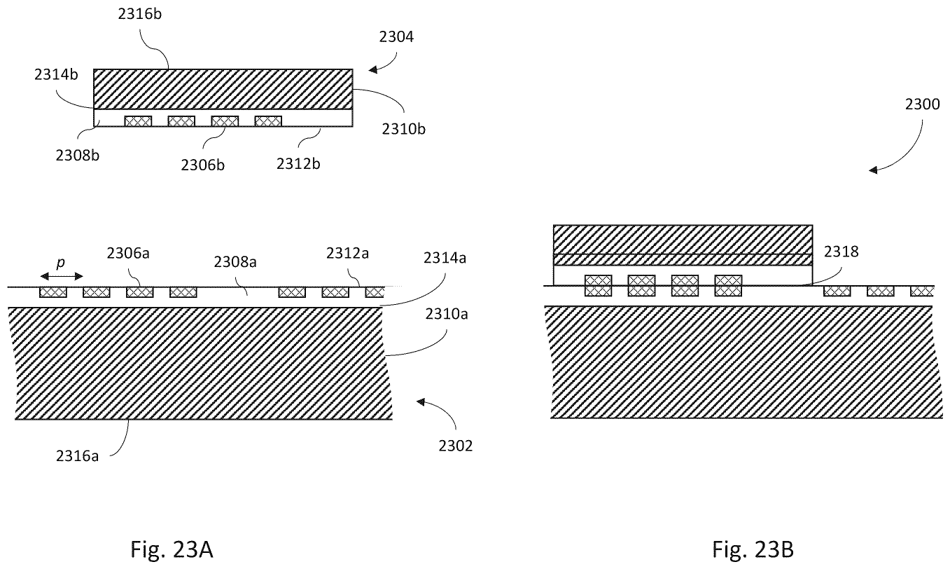

Various embodiments disclosed herein relate to directly bonded structures in which two or more elements can be directly bonded to one another without an intervening adhesive. FIGS. 23A and 23B schematically illustrate a process for forming a directly bonded structure without an intervening adhesive according to some embodiments. In FIGS. 23A and 23B, a bonded structure 2300 comprises two elements 2302 and 2304 that can be directly bonded to one another without an intervening adhesive. Two or more semiconductor elements (such as integrated device dies, wafers, etc.) 2302 and 2304 may be stacked on or bonded to one another to form the bonded structure 2300. Conductive features 2306a (e.g., contact pads, exposed ends of vias (e.g., TSVs), or a through substrate electrodes) of a first element 2302 may be electrically connected to corresponding conductive features 2306b of a second element 2304. Any suitable number of elements can be stacked in the bonded structure 2300. For example, a third element (not shown) can be stacked on the second element 2304, a fourth element (not shown) can be stacked on the third element, and so forth. Additionally or alternatively, one or more additional elements (not shown) can be stacked laterally adjacent one another along the first element 2302. In some embodiments, the laterally stacked additional element may be smaller than the second element. In some embodiments, the laterally stacked additional element may be two times smaller than the second element.

In some embodiments, the elements 2302 and 2304 are directly bonded to one another without an adhesive. In various embodiments, a non-conductive field region that includes a non-conductive or dielectric material can serve as a first bonding layer 2308a of the first element 2302 which can be directly bonded to a corresponding non-conductive field region that includes a non-conductive or dielectric material serving as a second bonding layer 2308b of the second element 2304 without an adhesive. The non-conductive bonding layers 2308a and 2308b can be disposed on respective front sides 2314a and 2314b of device portions 2310a and 2310b, such as a semiconductor (e.g., silicon) portion of the elements 2302, 2303. Active devices and/or circuitry can be patterned and/or otherwise disposed in or on the device portions 2310a and 2310b. Active devices and/or circuitry can be disposed at or near the front sides 2314a and 2314b of the device portions 2310a and 2310b, and/or at or near opposite backsides 2316a and 2316b of the device portions 2310a and 2310b. The non-conductive material can be referred to as a non-conductive bonding region or bonding layer 2308a of the first element 2302. In some embodiments, the non-conductive bonding layer 2308a of the first element 2302 can be directly bonded to the corresponding non-conductive bonding layer 2308b of the second element 2304 using dielectric-to-dielectric bonding techniques. For example, non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiments, the bonding layers 2308a and/or 2308b can comprise a non-conductive material such as a dielectric material, such as silicon oxide, or an undoped semiconductor material, such as undoped silicon. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SICOH dielectrics, silicon carbonitride or diamond-like carbon or a material comprising of a diamond surface. Such carbon-containing ceramic materials can be considered inorganic, despite the inclusion of carbon. In some embodiments, the dielectric materials do not comprise polymer materials, such as epoxy, resin or molding materials.

In various embodiments, direct hybrid bonds can be formed without an intervening adhesive. For example, nonconductive bonding surfaces 2312a and 2312b can be polished to a high degree of smoothness. The bonding surfaces 2312a and 2312b can be cleaned and exposed to a plasma and/or etchants to activate the surfaces 2312a and 2312b. In some embodiments, the surfaces 2312a and 2312b can be terminated with a species after activation or during activation (e.g., during the plasma and/or etch processes). Without being limited by theory, in some embodiments, the activation process can be performed to break chemical bonds at the bonding surfaces 2312a and 2312b, and the termination process can provide additional chemical species at the bonding surfaces 2312a and 2312b that improves the bonding energy during direct bonding. In some embodiments, the activation and termination are provided in the same step, e.g., a plasma to activate and terminate the surfaces 2312a and 2312b. In other embodiments, the bonding surfaces 2312a and 2312b can be terminated in a separate treatment to provide the additional species for direct bonding. In various embodiments, the terminating species can comprise nitrogen. For example, in some embodiments, the bonding surface(s) 2312a, 2312b can be exposed to a nitrogen-containing plasma. Further, in some embodiments, the bonding surfaces 2312a and 2312b can be exposed to fluorine. For example, there may be one or multiple fluorine peaks at or near a bonding interface 2318 between the first and second elements 2302, 2304. Thus, in the directly bonded structure 2300, the bonding interface 2318 between two non-conductive materials (e.g., the bonding layers 2308a and 2308b) can comprise a very smooth interface with higher nitrogen content and/or fluorine peaks at the bonding interface 2318. Additional examples of activation and/or termination treatments may be found throughout U.S. Pat. Nos. 9,564,414; 9,391,143; and 230,434,749, the entire contents of each of which are incorporated by reference herein in their entirety and for all purposes.

In various embodiments, conductive features 2306a of the first element 2302 can also be directly bonded to corresponding conductive features 2306b of the second element 2304. For example, a hybrid bonding technique can be used to provide conductor-to-conductor direct bonds along the bond interface 2318 that includes covalently direct bonded non-conductive-to-non-conductive (e.g., dielectric-to-dielectric) surfaces, prepared as described above. In various embodiments, the conductor-to-conductor (e.g., conductive feature 2306a to conductive feature 2306b) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, non-conductive (e.g., dielectric) bonding surfaces 2312a, 2312b (for example, inorganic dielectric surfaces) can be prepared and directly bonded to one another without an intervening adhesive as explained above. Conductive contact features (e.g., conductive features 2306a and 2306b which may be at least partially surrounded by non-conductive dielectric field regions within the bonding layers 2308a, 2308b) may also directly bond to one another without an intervening adhesive. In various embodiments, the conductive features 2306a, 2306b can comprise discrete pads at least partially embedded in the non-conductive field regions. In some embodiments, the conductive contact features can comprise exposed contact surfaces of through substrate vias (TSVs). In some embodiments, the respective conductive features 2306a and 2306b can be recessed below exterior (e.g., upper) surfaces (non-conductive bonding surfaces 2312a and 2312b) of the dielectric field region or non-conductive bonding layers 2308a and 2308b, for example, recessed by less than 30 nm, less than 20 nm, less than 235 nm, or less than 230 nm, for example, recessed in a range of 2 nm to 20 nm, or in a range of 4 nm to 230 nm. In various embodiments, prior to direct bonding, the recesses in the opposing elements can be sized such that the total gap between opposing contact pads is less than 235 nm, or less than 230 nm. The non-conductive bonding layers 2308a and 2308b can be directly bonded to one another without an adhesive at room temperature in some embodiments and, subsequently, the bonded structure 2300 can be annealed. Upon annealing, the conductive features 2306a and 2306b can expand and contact one another to form a metal-to-metal direct bond. Beneficially, the use of Direct Bond Interconnect, or DBI®, techniques commercially available from Xperi of San Jose, CA, can enable high density of conductive features 2306a and 2306b to be connected across the direct bond interface 2318 (e.g., small or fine pitches for regular arrays). In some embodiments, the pitch of the conductive features 2306a and 2306b, such as conductive traces embedded in the bonding surface of one of the bonded elements, may be less than 40 microns or less than 230 microns or even less than 2 microns. For some applications, the ratio of the pitch of the conductive features 2306a and 2306b to one of the dimensions (e.g., a diameter) of the bonding pad is less than 5, or less than 3 and sometimes desirably less than 2. In other applications, the width of the conductive traces embedded in the bonding surface of one of the bonded elements may range between 0.3 to 20 microns, e.g., in a range of 0.3 to 3 microns. In various embodiments, the conductive features 2306a and 2306b and/or traces can comprise copper, although other metals may be suitable.

Thus, in direct bonding processes, a first element 2302 can be directly bonded to a second element 2304 without an intervening adhesive. In some arrangements, the first element 2302 can comprise a singulated element, such as a singulated integrated device die. In other arrangements, as shown in FIGS. 23A and 23B, the first element 2302 can comprise a carrier or substrate (e.g., a wafer) that includes a plurality (e.g., tens, hundreds, or more) of device regions that, when singulated, form a plurality of integrated device dies. Similarly, the second element 2304 can comprise a singulated element, such as a singulated integrated device die, as shown in FIGS. 23A and 23B. In other arrangements, the second element 2304 can comprise a carrier or substrate (e.g., a wafer). The embodiments disclosed herein can accordingly apply to wafer-to-wafer, die-to-die, or die-to-wafer bonding processes. In wafer-to-wafer (W2W) processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the singulation process (e.g., saw markings if a saw singulation process is used).

As explained herein, the first and second elements 2302 and 2304 can be directly bonded to one another without an adhesive, which is different from a deposition process. In one application, a width of the first element 2302 in the bonded structure is similar to a width of the second element 2304. In some other embodiments, a width of the first element 2302 in the bonded structure 2300 is different from a width of the second element 2304. Similarly, the width or area of the larger element in the bonded structure may be at least 230% larger than the width or area of the smaller element. The first and second elements 2302 and 2304 can accordingly comprise non-deposited elements. Further, directly bonded structures 2300, unlike deposited layers, can include a defect region along the bond interface 2318 in which nanometer-scale voids (nanovoids) are present. The nanovoids may be formed due to activation of the bonding surfaces 2312a and 2312b (e.g., exposure to a plasma). As explained above, the bond interface 2318 can include concentration of materials from the activation and/or last chemical treatment processes. For example, in embodiments that utilize a nitrogen plasma for activation, a nitrogen peak can be formed at the bond interface 2318. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen peak can be formed at the bond interface 2318. In some embodiments, the bond interface 2318 can comprise silicon oxynitride, silicon oxycarbonitride, or silicon carbonitride. As explained herein, the direct bond can comprise a covalent bond, which is stronger than van Der Waals bonds. The bonding layers 2308a and 2308b can also comprise polished surfaces that are planarized to a high degree of smoothness.

In various embodiments, the metal-to-metal bonds between the contact pads 2306a and 2306b can be joined such that copper grains grow into each other across the bond interface 2318. In some embodiments, the copper can have grains oriented along the 2311 crystal plane for improved copper diffusion across the bond interface 2318. The bond interface 2318 can extend substantially entirely to at least a portion of the bonded conductive features 2306a and 2306b, such that there is substantially no gap between the non-conductive bonding layers 2308a and 2308b at or near the bonded conductive features 2306a and 2306b. In some embodiments, a barrier layer may be provided under the conductive features 2306a and 2306b (e.g., which may include copper). In other embodiments, however, there may be no barrier layer under the conductive features 2306a and 2306b, for example, as described in U.S. Pat. No. 231,195,748, which is incorporated by reference herein in its entirety and for all purposes.

Beneficially, the use of the hybrid bonding techniques described herein can enable extremely fine pitch between adjacent contact pads 2306a and 2306b, and/or small pad sizes. For example, in various embodiments, the pitch p (i.e., the distance from edge-to-edge or center-to-center, as shown in FIG. 23A) between adjacent conductive features 2306a (or 2306b) can be in a range of 0.5 microns to 50 microns, in a range of 0.75 microns to 25 microns, in a range of 23 micron to 25 microns, in a range of 23 micron to 230 microns, or in a range of 23 micron to 5 microns. Further, a major lateral dimension (e.g., a pad diameter) can be small as well, e.g., in a range of 0.25 microns to 30 microns, in a range of 0.25 microns to 5 microns, or in a range of 0.5 microns to 5 microns.

In some aspects, the techniques described herein relate to an assembly including: a substrate having a top surface and a bottom surface; one or more layers formed on the top surface of the substrate, the one or more layers and the substrate including a plurality of devices to be singulated into dies and a scribe region separating the devices, at least one layer of the one more layers including a first dielectric material; and a trench at least partially overlapping the scribe region and at least partially filled with a second dielectric material that is different from the first dielectric material.

In some aspects, the techniques described herein relate to an assembly, wherein the second dielectric material has a higher dielectric constant than a dielectric constant of the first dielectric material.

In some aspects, the techniques described herein relate to an assembly, wherein the first dielectric material is an inorganic material.

In some aspects, the techniques described herein relate to an assembly, wherein the first dielectric material includes one or more of fluorine-doped silicon dioxide, porous silicon dioxide, and a spin-on silicon based polymeric dielectric.

In some aspects, the techniques described herein relate to an assembly, wherein the first dielectric material has a dielectric constant of from about 1.8 to about 3.6.

In some aspects, the techniques described herein relate to an assembly, wherein the first dielectric material is an interlayer dielectric in one or more interconnect levels.

In some aspects, the techniques described herein relate to an assembly, further including a top buffer layer.

In some aspects, the techniques described herein relate to an assembly, wherein the top buffer layer is a dielectric layer.

In some aspects, the techniques described herein relate to an assembly, wherein the top buffer layer includes at least one of silicon dioxide, silicon nitride, silicon oxynitride or silicon carbonitride.

In some aspects, the techniques described herein relate to an assembly, wherein the top buffer layer has a thickness of from about 0.2 μm to about 10 μm.

In some aspects, the techniques described herein relate to an assembly, further including: a sub-assembly that is directly bonded to a top surface of the one or more layers.

In some aspects, the techniques described herein relate to an assembly including: a substrate having a top surface and a bottom surface; one or more layers including one or more materials formed on the top surface of the substrate, the one or more layers and the substrate including a plurality of devices to be singulated into dies and a separating region between devices of the plurality of devices, the separating region including a fill material, wherein the fill material is different from at least one material of the plurality of devices.

In some aspects, the techniques described herein relate to an assembly, wherein at least one layer of the one or more layers includes a first dielectric material, and wherein the fill material includes an insulating material with a higher dielectric constant than the first dielectric material.

In some aspects, the techniques described herein relate to an assembly, wherein the fill material abuts edges of two or more interlayer dielectric materials of the one or more layers.

In some aspects, the techniques described herein relate to an assembly, wherein the fill material extends from a position between the bottom surface of the substrate and the top surface of the substrate to a position below the top surface of the substrate or to a layer of the one or more layers formed on the top surface of the substrate.

In some aspects, the techniques described herein relate to an assembly, wherein the fill material is an inorganic dielectric material.

In some aspects, the techniques described herein relate to an assembly, wherein the first dielectric material includes one or more of fluorine-doped silicon dioxide, porous silicon dioxide, and a spin-on silicon based polymeric dielectric.

In some aspects, the techniques described herein relate to an assembly, wherein the first dielectric material has a dielectric constant of from about 3 to about 10.

In some aspects, the techniques described herein relate to an assembly, wherein the fill material includes an interlayer dielectric in one or more interconnect levels.

In some aspects, the techniques described herein relate to an assembly, wherein the fill material includes one or more of silicon dioxide, silicon nitride, and silicon oxynitride.

In some aspects, the techniques described herein relate to an assembly, further including a top buffer layer.

In some aspects, the techniques described herein relate to an assembly, wherein the top buffer layer is a dielectric layer.

In some aspects, the techniques described herein relate to an assembly, wherein the top buffer layer includes at least one of silicon dioxide, silicon nitride, silicon oxynitride, or silicon carbonitride.

In some aspects, the techniques described herein relate to an assembly, where the top buffer layer has a thickness of from about 0.2 μm to about 10 μm.

In some aspects, the techniques described herein relate to an assembly, further including a sub-assembly that is directly bonded to a top surface of the one or more layers.

In some aspects, the techniques described herein relate to a method including: providing a first assembly including a substrate and one or more layers disposed on a top surface of the substrate, the one or more layers and the substrate including a plurality of devices to be singulated into dies and a scribe region separating the devices; forming at least one trench at least partially overlapping with the scribe region; and depositing a dielectric material in the at least one trench.

In some aspects, the techniques described herein relate to a method, further including: before depositing the dielectric material in the at least one trench, forming a trench buffer layer in the at least one trench.

In some aspects, the techniques described herein relate to a method, wherein the trench buffer layer includes SiO2, SiON, SiN or SiCN.

In some aspects, the techniques described herein relate to a method, wherein the trench buffer layer has a thickness of from about 0.2 μm to about 10 μm.

In some aspects, the techniques described herein relate to a method, further including: depositing a surface dielectric on a top surface of the one or more layers.

In some aspects, the techniques described herein relate to a method, wherein the surface dielectric includes at least one of silicon dioxide, silicon nitride, silicon oxynitride, and silicon carbonitride.

In some aspects, the techniques described herein relate to a method, wherein the surface dielectric has a thickness of from about 3 μm to about 10 μm.

In some aspects, the techniques described herein relate to a method, further including: bonding a top surface of the substrate to a carrier wafer; and removing a portion of the substrate, wherein the removing begins at a bottom surface of the substrate and extends a distance toward the top surface of the substrate.

In some aspects, the techniques described herein relate to a method, where removing the portion of the substrate exposes the dielectric material in the at least one trench.

In some aspects, the techniques described herein relate to a method, further including: dicing the assembly, the dicing including separating the plurality of devices into the dies by cutting through the dielectric material in the at least one trench.

In some aspects, the techniques described herein relate to a method, wherein two trenches are formed in the scribe region, wherein a center portion of the scribe region is substantially unchanged.

In some aspects, the techniques described herein relate to a method, further including: removing a portion of the substrate that aligns with the at least one trench while not removing a portion of the substrate that aligns with the plurality of devices, wherein the removing exposes the dielectric material; removing the dielectric material; and forming a second dielectric material in the at least one trench.

In some aspects, the techniques described herein relate to a method, wherein the at least one trench includes two trenches.

In some aspects, the techniques described herein relate to a method, further including: forming a second trench in the substrate by removing a portion of the substrate that aligns with the at least trench while not removing a portion of the substrate that aligns with the plurality of devices, wherein the removing exposes the dielectric material; and forming a second dielectric material in the second trench.

In some aspects, the techniques described herein relate to a method, further including: before forming the second dielectric material, forming a buffer layer in the second trench.

In some aspects, the techniques described herein relate to a method, wherein forming the at least one trench in the scribe region includes removing material starting from a bottom surface of the substrate.

In some aspects, the techniques described herein relate to a method including: providing a first wafer including a first plurality of devices to be singulated into first dies and at least one first trench, the at least one first trench filled with a first dielectric material that is different from a second dielectric material in adjacent metallization layers of the first plurality of devices; providing a second wafer including a second plurality of devices to be singulated into second dies and at least one second trench, the at least one second trench filled with a third dielectric material that is different from a fourth dielectric material in adjacent metallization layers of the second plurality of devices; and directly bonding a top surface of the first wafer to a top surface of the second wafer.

In some aspects, the techniques described herein relate to a method, wherein the first dielectric material has a higher dielectric constant that the second dielectric material, wherein the third dielectric material has a higher dielectric constant than the fourth dielectric material.

In some aspects, the techniques described herein relate to a method, further including thinning the second wafer after directly bonding.

In some aspects, the techniques described herein relate to a method, wherein first dielectric material is the same as the third dielectric material.

In some aspects, the techniques described herein relate to a method, wherein the first dielectric material and the second dielectric material are inorganic.

In some aspects, the techniques described herein relate to a method including: providing a first wafer including a first plurality of devices to be singulated into first dies and at least one first void, the at least one first void filled with a first dielectric material having a higher dielectric constant than a second dielectric material of interlayer dielectric layers in the first plurality of devices; directly bonding a plurality of second dies to a top surface of the first wafer; providing a second dielectric material between each device of the first plurality of devices; and bonding a second wafer to a top surface of the plurality of second dies.

In some aspects, the techniques described herein relate to a method, further including: thinning the first wafer, the thinning exposing the least one first void filled with the first dielectric material.

In some aspects, the techniques described herein relate to a method, wherein each die of the plurality of second dies includes a third dielectric material disposed at an edge of at least one of the second dies.

In some aspects, the techniques described herein relate to a method including: providing a first wafer including a first plurality of devices to be singulated into first dies and at least one first channel, the at least one first channel filled with a first dielectric material that is different from a second dielectric material employed in interconnect levels of the first plurality of devices; directly bonding a top surface of the first wafer to a carrier wafer; thinning the first wafer after directly bonding, the thinning including removing material from a bottom surface of the first wafer; directly bonding a top surface a plurality of second dies to the bottom surface of the first wafer; providing a second dielectric material between the second dies; directly bonding a substrate to bottom surfaces of the second dies; and removing the carrier wafer.

In some aspects, the techniques described herein relate to a method, wherein the at least first dielectric material has a higher dielectric constant than the second dielectric material.

In some aspects, the techniques described herein relate to a semiconductor device including: a plurality of layers, each layer including at least one metallic interconnect and at least one interlayer dielectric material, wherein at least one layer includes at least one void, the at least one void filled with filler material(s) that are different from the at least one interlayer dielectric material, wherein the at least one void is no more than a threshold distance from the at least one metallic interconnect.

In some aspects, the techniques described herein relate to a semiconductor device, wherein the filler material(s) have a dielectric constant that is greater than a dielectric constant of the at least one interlayer dielectric material.

In some aspects, the techniques described herein relate to a semiconductor device, wherein the filler material(s) includes an inorganic dielectric material.

In some aspects, the techniques described herein relate to a semiconductor device, wherein the filler material(s) are configured to arrest cracks from a peripheral region through the interlayer dielectric material.

### Additional Embodiments

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

1. An assembly comprising:
a substrate having a top surface and a bottom surface;
one or more layers formed on the top surface of the substrate, the one or more layers and the substrate comprising a plurality of devices to be singulated into dies and a scribe region separating the devices, at least one layer of the one more layers comprising a first dielectric material; and
a trench at least partially overlapping the scribe region and at least partially filled with a second dielectric material that is different from the first dielectric material.

2. The assembly of claim 1, wherein the second dielectric material has a higher dielectric constant than a dielectric constant of the first dielectric material.

3. The assembly of claim 1, wherein the first dielectric material is an inorganic material.

4. (canceled)

5. The assembly of claim 2, wherein the first dielectric material has a dielectric constant of from about 1.8 to about 3.6.

6. The assembly of claim 1, wherein the first dielectric material is an interlayer dielectric in one or more interconnect levels.

7. The assembly of claim 1, further comprising a top buffer layer.

8. (canceled)

9. (canceled)

10. (canceled)

11. The assembly of claim 1, further comprising:
a sub-assembly that is directly bonded to a top surface of the one or more layers.

12.-25. (canceled)

26. A method comprising:
providing a first assembly comprising a substrate and one or more layers disposed on a top surface of the substrate, the one or more layers and the substrate comprising a plurality of devices to be singulated into dies and a scribe region separating the devices;
forming at least one trench at least partially overlapping with the scribe region; and
depositing a dielectric material in the at least one trench.

27. The method of claim 26, further comprising:
before depositing the dielectric material in the at least one trench, forming a trench buffer layer in the at least one trench.

28. (canceled)

29. (canceled)

30. The method of claim 26, further comprising:
depositing a surface dielectric on a top surface of the one or more layers.

31. (canceled)

32. (canceled)

33. The method of claim 26, further comprising:
bonding a top surface of the substrate to a carrier wafer; and
removing a portion of the substrate, wherein the removing begins at a bottom surface of the substrate and extends a distance toward the top surface of the substrate.

34. The method of claim 33, where removing the portion of the substrate exposes the dielectric material in the at least one trench.

35. The method of claim 34, further comprising:
dicing the assembly, the dicing comprising separating the plurality of devices into the dies by cutting through the dielectric material in the at least one trench.

36. The method of claim 26, wherein two trenches are formed in the scribe region, wherein a center portion of the scribe region is substantially unchanged.

37. The method of claim 33, further comprising:
removing a portion of the substrate that aligns with the at least one trench while not removing a portion of the substrate that aligns with the plurality of devices, wherein the removing exposes the dielectric material;
removing the dielectric material; and
forming a second dielectric material in the at least one trench.

38. (canceled)

39. The method of claim 33, further comprising:
forming a second trench in the substrate by removing a portion of the substrate that aligns with the at least trench while not removing a portion of the substrate that aligns with the plurality of devices, wherein the removing exposes the dielectric material; and
forming a second dielectric material in the second trench.

40. (canceled)

41. (canceled)

42. A method comprising:
providing a first wafer comprising a first plurality of devices to be singulated into first dies and at least one first trench, the at least one first trench filled with a first dielectric material that is different from a second dielectric material in adjacent metallization layers of the first plurality of devices;
providing a second wafer comprising a second plurality of devices to be singulated into second dies and at least one second trench, the at least one second trench filled with a third dielectric material that is different from a fourth dielectric material in adjacent metallization layers of the second plurality of devices; and
directly bonding a top surface of the first wafer to a top surface of the second wafer.

43. The method of claim 42, wherein the first dielectric material has a higher dielectric constant that the second dielectric material,
wherein the third dielectric material has a higher dielectric constant than the fourth dielectric material.

44. The method of claim 42, further comprising thinning the second wafer after directly bonding.

45. (canceled)

46. The method of claim 44, wherein the first dielectric material and the second dielectric material are inorganic.

47.-55. (canceled)
